(19) United States
(12) Patent Application Publication
(10) Pub. No.: US 2009/0297990 A1
(43) Pub. Date: Dec. 3, 2009

(54) Liquid holding apparatus, liquid holding method, exposure apparatus, exposing method, and device fabricating method

(75) Inventors: Kazuya ONO, Saitama-shi (JP); Dai ARAI, Tokyo (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/453,158

(22) Filed: Apr. 30, 2009

Related U.S. Application Data
(63) Continuation of application No. PCT/JP2007/071211, filed on Oct. 31, 2007.

(30) Foreign Application Priority Data
Oct. 31, 2006 (JP) 2006-296453
Apr. 6, 2007 (JP) 2007-100339

(51) Int. Cl. G03F 7/20; G03B 27/52; G03B 27/32

(52) U.S. Cl. 430/325; 355/30; 355/77

(57) ABSTRACT

Liquid is held in a prescribed region between a first object and a second object. An electrostatic holder holds the liquid by electrostatic force.

### CROSS-REFERENCE TO RELATED APPLICATION

Priority is claimed on Japanese Patent Application No. 2006-296453, filed on Oct. 31, 2006, and Japanese Patent Application No. 2007-100339, filed on Apr. 6, 2007, the content of which are incorporated herein by reference.

### BACKGROUND

1. Field of the Invention

The present invention relates to: a liquid holding apparatus and liquid holding method; an exposure apparatus and exposing method; and a device fabricating method.

2. Description of Related Art

In the photolithography process, which is one of the manufacturing processes of microdevices such as semiconductor devices and liquid crystal display devices, an exposure apparatus is used which projects a pattern formed on a mask onto a photosensitive substrate. This exposure apparatus has a mobile mask stage which holds the mask, and a mobile substrate stage which holds the substrate, and the mask pattern is projected onto the substrate via a projection optical system while the mask stage and substrate stage are sequentially moved. In the fabrication of microdevices, miniaturization of the pattern formed on the substrate is required in order to achieve higher density of the device. In order to meet this requirement, it would be desirable to achieve still higher resolution of the exposure apparatus. As one means of achieving the higher resolution, a liquid immersion exposure apparatus like that disclosed in PCT International Publication WO99/49504 has been proposed, which fills an optical path space of exposure light between a substrate and a projection optical system with liquid, and which exposes the substrate via the projection optical system and the liquid.

However, the following problems exist with respect to the aforementioned background art.

With respect to the exposure apparatus, there is a demand to increase the moving speed of the substrate (substrate stage) with the objective of improving device productivity and the like. However, as the liquid between the substrate and the projection optical system is mainly held in place by surface tension, if the substrate (substrate stage) is moved at high speed, it is possible that it may become difficult to fill the optical path space of the exposure light with liquid in a desired state, and that exposure accuracy and measurement accuracy via the liquid may deteriorate.

For example, when problems occur in conjunction with higher speed movement of the substrate (substrate stage) such as inability to fully fill the optical path space of the exposure light with liquid, and generation of air bubbles in the liquid, it is possible that problems may arise such as the exposure light not reaching the substrate in a satisfactory manner, and generation of defects in the pattern formed on the substrate. Moreover, in conjunction with higher speed movement of the substrate (substrate stage), it is also possible that the problem of leakage of the liquid that fills the optical path space may occur. When the liquid leaks, this causes problems such as corrosion and malfunction of peripheral members and equipment. Moreover, if the leaked liquid or unrecovered liquid forms droplets, and remains on the substrate, this may cause the problem of liquid adhesion mark (so-called “water mark”) formation on the substrate due to evaporation of residual liquid (droplets). There is also the concern that this may lead to: thermal deformation of the substrate and substrate stage due to the heat from evaporation of the leaked liquid; deterioration in exposure accuracy including the accuracy of pattern superimposition on the substrate due to fluctuations in the environment (humidity, degree of cleanliness, etc.) in which the exposure apparatus is situated; and deterioration in the accuracy of various types of measurement employing interferometers and the like. Moreover, when the substrate becomes wet due to leaked liquid, liquid also adheres to the conveyance system that holds the wet substrate, resulting in concern of greater damage. In conjunction with higher speed movement of the substrate (substrate stage), it is also possible that the region covered with liquid may greatly enlarge, causing the associated problem that the entire exposure apparatus would also greatly enlarge.

The object of the various aspects of the present invention is to offer a liquid holding apparatus, liquid holding method, exposure apparatus, exposing method, and device fabricating method that enable the optical path space of the exposure light to be filled with liquid in a desired state even when performing exposure while moving the substrate.

### SUMMARY

A first aspect of the present invention offers a liquid holding apparatus which holds a liquid in a prescribed region between a first object and a second object, wherein the liquid holding apparatus is provided with an electrostatic holder that holds the liquid by electrostatic force.

Accordingly, under the first aspect, as the liquid can be held in a prescribed region between the first object and the second object not only by the surface tension of the liquid, but also by electrostatic force, it is possible to fill an optical path space of exposure light with liquid in a desired state, and hold this liquid, even when, for example, a substrate is moved in a prescribed direction as the second object.

A second aspect of the present invention offers an exposure apparatus which exposes a substrate with an image of a pattern via a liquid immersion region, and which uses the aforementioned liquid holding apparatus in order to form the liquid immersion region.

Accordingly, under the second aspect, it is possible to fill an optical path space of exposure light with liquid in a desired state, and hold this liquid, even when exposure is conducted while moving the substrate in a prescribed direction.

According to a third aspect of the present invention, a device fabricating method that employs the aforementioned exposure apparatus is used.

Accordingly, under the third aspect, it is possible to fabricate devices that employ an exposure apparatus capable of filling an optical space of exposure light with liquid in a desired state.

A fourth aspect of the present invention offers a liquid holding method which holds a liquid in a prescribed region between a first object and a second object, and which uses electrostatic force to hold the liquid.

Accordingly, under the fourth aspect, as liquid can be held in a prescribed region between the first object and second object not only by the surface tension of the liquid, but also by electrostatic force, it is possible to fill an optical path space of exposure light with liquid in a desired state, and hold this liquid, even when, for example, a substrate is moved in a prescribed direction as the second object.

The fifth aspect of the present invention offers an immersion exposure apparatus which exposes a substrate with exposure light via a liquid of a immersion space, and which includes: an immersion member that is provided with a prescribed surface and that is capable of forming a liquid immersion space between the prescribed surface and the surface of an opposing object; and a supply port that supplies a liquid for formation of the immersion space, and that forms the immersion space with a liquid charged to a prescribed polarity in order to impart prescribed condition to the state of an interface of the liquid of the immersion space.

Accordingly, under the fifth aspect, it is possible to fill the optical path space of exposure light with the liquid in a desired state, and hold this liquid, even when performing exposure while moving the substrate in a prescribed direction.

According to a sixth aspect of the present invention, a device fabricating method is offered that includes exposing a substrate using the aforementioned immersion exposure apparatus, and developing the exposed substrate.

Accordingly, under the sixth aspect, it is possible to fabricate a device using an exposure apparatus capable of filling an optical path space of exposure light with a liquid in a desired state.

The seventh aspect of the present invention offers an exposing method which exposes a substrate with exposure light via a liquid of an immersion space, and which forms an immersion space with a liquid charged to a prescribed polarity in order to impart a prescribed condition to the state of an interface of the liquid of the liquid immersion space.

Accordingly, under the seventh aspect it is possible to fill the optical path space of the exposure light with the liquid in a desired state, and hold this liquid, even when performing exposure while moving the substrate in a prescribed direction.

According to an eighth aspect of the present invention, a device fabricating method is offered which includes exposing a substrate using the aforementioned exposing method, and developing the exposed substrate.

Accordingly, under the eighth aspect, it is possible to fabricate a device using an exposing method capable of filling an optical path space of exposure light with a liquid in a desired state.

Under the various aspects of the present invention, an optical path space of exposure light is filled with a liquid in a desired state, and this liquid is held, thereby enabling satisfactory conduct of exposure treatment and measurement treatment via the liquid.

### BRIEF DESCRIPTION OF THE DRAWINGS

FIG. 1 is a schematic block diagram that shows an exposure apparatus having a liquid holding apparatus of a first embodiment.

FIG. 2 is a partial, broken, schematic, oblique view that shows the vicinity of a nozzle member of the first embodiment.

FIG. 3 is an oblique view of a nozzle member of the first embodiment seen from the underside.

FIG. 4 is a lateral cross-sectional view that is parallel to the XZ plane of FIG. 2.

FIG. 5 is a lateral cross-sectional view that is parallel to the YZ plane of FIG. 2.

FIG. 6 shows a state in which polarization of electric charge has occurred in the liquid.

FIG. 7 is a partial, broken, schematic, oblique view that shows the vicinity of a nozzle member of a second embodiment.

FIG. 8 shows a portion of the exposure apparatus of a third embodiment.

FIG. 9 is a schematic drawing for explaining an example of a charging apparatus that charges the liquid.

FIG. 10 is a schematic drawing for explaining an example of a charging apparatus that charges the substrate and the substrate stage of the third embodiment.

FIG. 11A is a schematic drawing for explaining an example of the operation of the exposure apparatus of the third embodiment.

FIG. 11B is a schematic drawing for explaining an example of the operation of the exposure apparatus of the third embodiment.

FIG. 12A is a schematic drawing for explaining an example of the operation of the exposure apparatus of the third embodiment.

FIG. 12B is a schematic drawing for explaining an example of the operation of the exposure apparatus of the third embodiment.

FIG. 13 shows a portion of the exposure apparatus of a fourth embodiment.

FIG. 14 is a cross-sectional fragmentary view along the A-A line of FIG. 13

FIG. 15 shows another example of the exposure apparatus of the fourth embodiment.

FIG. 16 is a schematic drawing for explaining an example of a charging apparatus that charges the substrate and the substrate stage of a fifth embodiment.

FIG. 17 is a schematic drawing for explaining an example of a charging apparatus that charges the substrate and the substrate stage of a sixth embodiment.

FIG. 18 is a schematic drawing for explaining an example of a charging apparatus that charges the substrate and the plate member of a seventh embodiment.

FIG. 19A is a schematic drawing for explaining an example of the operation of the exposure apparatus of the seventh embodiment.

FIG. 19B is a schematic drawing for explaining an example of the operation of the exposure apparatus of the seventh embodiment.

FIG. 19C is a schematic drawing for explaining an example of the operation of the exposure apparatus of the seventh embodiment.

FIG. 19D is a schematic drawing for explaining an example of the operation of the exposure apparatus of the seventh embodiment.

FIG. 20 is a schematic drawing for explaining an example of a charging apparatus that charges the substrate and the plate member of an eighth embodiment.

FIG. 21 is a flow chart diagram that depicts an example of a microdevice manufacturing process.

### DESCRIPTION OF EMBODIMENTS

Embodiments of the liquid holding apparatus, liquid holding method, exposure apparatus, exposing method, and device fabricating method of the present invention are described below with reference to drawings, but the present invention is not limited thereby.

### First Embodiment

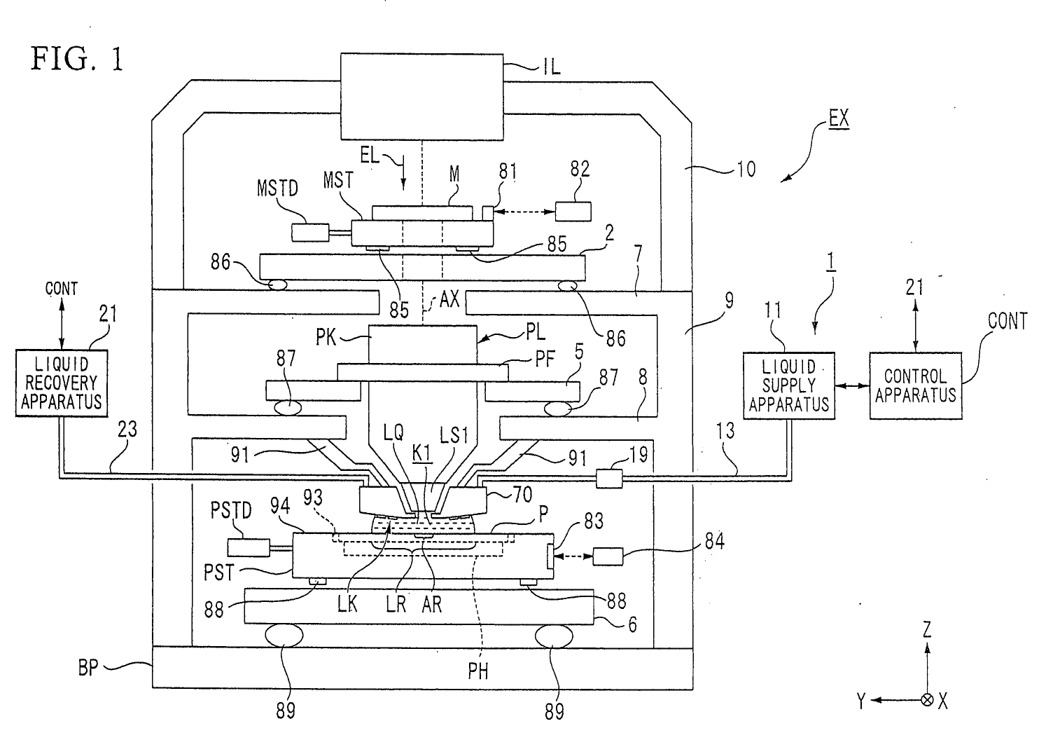

FIG. 1 is a schematic block diagram that shows an exposure apparatus having a liquid holding apparatus of a first embodiment.

In FIG. 1, an exposure apparatus EX is provided with a mobile mask stage MST which holds a mask M, a mobile substrate stage PST which holds a substrate P that constitutes a second object, an illumination optical system IL which illuminates the mask M held in the mask stage MST with exposure light (an exposure beam) EL, a projection optical system (optical member) PL which casts and projects a pattern image of the mask M that is irradiated with exposure light EL onto the substrate P that is held in the substrate stage PST, and a control apparatus CONT which controls the operations of the entire exposure apparatus EX.

The exposure apparatus EX of the present embodiment is a liquid immersion exposure apparatus which applies a liquid immersion method that serves to substantially shorten exposure light wavelength, improve resolution, and substantially widen depth of focus, and is provided with a liquid immersion mechanism 1 that is designed to fill an optical path space K1 of exposure light EL in the vicinity of an image plane of the projection optical system PL with a liquid LQ. The liquid immersion mechanism 1 includes: a nozzle member 70 as a first object which is provided in tile vicinity of the optical path space K1, and which has supply ports 12 that supply the liquid LQ and recovery ports 22 that recover the liquid LQ; a liquid supply apparatus 11 which supplies the liquid LQ via the supply ports 12 that are provided in the nozzle member 70 and supply tubes 13; recovery ports 22 provided in the nozzle member 70; and a liquid recovery apparatus 21 that recovers the liquid LQ via recovery tubes 23. As described below in detail, inside the nozzle member 70, channels (supply channels) 14 are provided that connect the supply ports 12 and supply tubes 13, and channels (recovery channels) 24 are provided that connect the recovery ports 22 and recovery tubes 23. In FIG. 1, the supply ports, recovery ports, supply channels and recovery channels are not illustrated. The nozzle member 70 is given an annular shape so that it surrounds a last optical element LS1 that is the closest of the multiple optical elements of the projection optical system PL to the image plane of the projection optical system PL.

The exposure apparatus EX of the present embodiment adopts a local liquid immersion method in which a liquid immersion region (prescribed region) LR of the liquid LQ—that is larger than a projection region AR of the projection optical system PL and smaller than the substrate P—is locally formed on a portion of the substrate P containing the projection region AR. The exposure apparatus EX projects a pattern of the mask M onto the substrate P by filling the optical path space K1 of the exposure light EL with the liquid LQ between the last optical element LS1 that is closest to the image plane of the projection optical system PL and the substrate P that is disposed on the image plane side of the projection optical system PL at least during transfer of the pattern image of the mask M to the substrate P, and by irradiating the substrate P with the exposure light EL that transits the mask M via the liquid LQ that fills the projection optical system PL and the optical path space K1. By supplying the liquid LQ in a prescribed amount using the liquid supply apparatus 11 of the liquid immersion mechanism 1, and by recovering the liquid LQ in a prescribed amount using the liquid recovery apparatus 21, the control apparatus CONT fills the optical path space K1 with the liquid LQ, and locally forms the liquid immersion region LR of the liquid LQ on the substrate P.

In the below description, the case is described in which the optical path space K1 is filled with the liquid LQ in a state where the substrate P is disposed in a position that can be irradiated by the exposure light EL, that is, in a state where the projection optical system PL and substrate P are mutually opposed, but the same applies for the case in which the optical path space K1 is filled with the liquid LQ in a state where an object other than the substrate P (e.g., a substrate holder that holds the upper surface of the substrate stage PST and the substrate P) opposes the projection optical system PL.

In the present embodiment, an exemplary case is described wherein a scanning type exposure apparatus (a so-called scanning stepper) is used as the exposure apparatus EX, which exposes the substrate P with a pattern formed on the mask M while synchronously moving the mask M and substrate P in the scanning directions. In the below description, the directions in which the mask M and substrate P synchronously move (the scanning directions) within the horizontal plane are the Y axial directions, the directions that are orthogonal to the Y axial directions within the horizontal plane are the X axial directions (the non-scanning directions), and the directions that are perpendicular to the X and Y axial directions and that coincide with an optical axis AX of the projection optical system PL are the Z axial directions. In addition, the rotational (inclined) directions around the X, Y, and Z axes are the θX, θY, and θZ directions, respectively. Furthermore, the “substrate” described herein includes, for example, one wherein a photosensitive material (photoresist) is applied to a base material such as a semiconductor wafer (silicon wafer) like a silicon wafer, or one wherein various types of film such as protective film (top-coat film) may be applied in addition to the photosensitive material. The “mask” includes a reticle in which a device pattern is formed that is reduction-projected onto the substrate.

The exposure apparatus EX includes a base BP that is provided on a floor, and main columns 9 that are installed on the base BP. In the main columns 9, upper steps 7 and lower steps 8 are formed that project toward the inside. The illumination optical system IL irradiates the mask M held in the mask stage MST with the exposure light EL, and is supported by support frames 10 that are fixed to the upper parts of the main columns 9.

The illumination optical system IL has an optical integrator that homogenizes the intensity of the light beams emitted from a light source of the exposure light, a condenser lens that concentrates the exposure light EL from the optical integrator, a relay lens system, a field stop that sets the irradiation region of the exposure light EL on the mask M, and so on. A prescribed irradiation region on the mask M is irradiated with the exposure light EL, which has a uniform luminous flux intensity distribution by the illumination optical system IL. Examples of light that can be used as the exposure light EL emitted from the illumination optical system IL include: deep ultraviolet light (DUV light) such as bright line (g-line, h-line, or i-line) light emitted from, for example, a mercury lamp and KrF excimer laser light (248 nm wavelength); and vacuum ultraviolet light (VUV light) such as ArF excimer laser light (193 nm wavelength) and F₂ laser light (157 nm wavelength). ArF excimer laser light is used in the present embodiment.

In the present embodiment, pure water is used as the liquid LQ. Pure water is capable of transmitting not only ArF excimer laser light, but also deep ultraviolet light (DUV light) such as bright line (g-line, h-line, or i-line) light emitted from, for example, a mercury lamp and KrF excimer laser light (248 nm wavelength).

The mask stage MST movably holds the mask M. The mask stage MST holds the mask M by vacuum contact (or electrostatic contact). Air bearings 85 that are non-contact bearings are multiply provided on the bottom face of the mask stage MST. The mask stage MST is noncontactually supported by the air bearings 85 with respect to an upper surface (guide surface) of a mask stage base plate 2. Apertures through which the pattern image of the mask M transit are respectively formed in the central parts of the mask stage MST and mask stage base plate 2. The mask stage base plate 2 is supported by the upper steps 7 of the main columns 9 via vibration isolators 86. That is, the mask stage MST is configured to be supported by upper steps 7 of the main columns 9 via the vibration isolators 86 and the mask stage base plate 2. By means of the vibration isolators 86, the mask stage base plate 2 and main columns 9 are vibrationally separated so that vibration of the main columns 9 is not transmitted to the mask stage base plate 2 that supports the mask stage MST.

By the driving of a mask stage drive apparatus MSTD containing linear motors and the like controlled by the control apparatus CONT, the mask stage MST is capable of two-dimensional movement within the vertical plane—that is, within the XY plane—along the optical axis AX of the projection optical system PL, and is capable of micro-rotation in the θZ direction on the mask stage base plate 2 in a state where the mask M is held. A moving mirror 81 is provided on the mask stage MST. Furthermore, a laser interferometer 82 is provided at a prescribed position relative to the mask stage MST. The position in the two-dimensional direction and the rotational angle in the θZ direction (including, depending on circumstances, the rotational angles in the θX and θY directions) of the mask M on the mask stage MST is measured in real time by the laser interferometer 82 using the moving mirror 81. The measurement results of the laser interferometer 82 is outputted to the control apparatus CONT. The control apparatus CONT drives the mask stage drive apparatus MSTD based on the measurement results of the laser interferometer 82, and conducts positional control of the mask M held in the mask stage MST.

The projection optical system PL projects the pattern of the mask M onto the substrate P at a prescribed projection magnification β. It has multiple optical elements, and these optical elements are held by a lens barrel PK. In the present embodiment, the projection optical system PL is a reduction system, of which the projection magnification β is, for example, ¼, ⅕, or ⅛. Furthermore, the projection optical system PL may also be either a unity magnification system or an enlargement system. In addition, the projection optical system PL may be: a dioptric system that does not include catoptric elements; a catoptric system that does not include dioptric elements; or a catadioptric system that includes both catoptric elements and dioptric elements. In addition, the projection optical system PL may form either an inverted image or an erect image. Of the multiple optical elements of the projection optical system PL, the last optical element LS1 that is closest to the image plane of the projection optical system PL is more exposed than the lens barrel PK.

A flange PF is provided at the periphery of the lens barrel PK that holds the projection optical system PL, and the projection optical system PL is supported by lens barrel base plates 5 via the flange PF. The lens barrel base plates 5 are supported by the lower steps 8 of the main columns 9 via vibration isolators 87. That is, the projection optical system PL is configured to be supported by the lower steps 8 of the main columns 9 via the vibration isolators 87 and lens barrel base plates 5. Moreover, the lens barrel base plates 5 and main columns 9 are vibrationally isolated by the vibration isolators 87 so that vibration of the main columns 9 is not transmitted to the lens barrel base plates 5 that support the projection optical system PL.

The substrate stage PST has a substrate holder PH that supports the substrate P, and the substrate P is movably held by the substrate holder PH. The substrate holder PH holds the substrate P by vacuum contact or the like. A recessed part 93 is provided in the substrate stage PST, and the substrate holder PH that serves to hold the substrate P is disposed in the recessed part 93. An upper surface 94 of the substrate stage PST apart from the recessed part 93 is a flat surface of approximately the same height as (flush with) the surface of the substrate P held by the substrate holder P. Furthermore, if the optical path space K1 can be continuously filled with the liquid LQ, it is also acceptable to have a step between the upper surface 94 of the substrate stage PST and the surface of the substrate P held by the substrate holder PH.

Air bearings 88 that are non-contact bearings are multiply provided on the bottom face of the substrate stage PST. The substrate stage PST is noncontactually supported on the upper surface (guide surface) of a substrate stage base plate 6 by the air bearings 88. The substrate stage base plate 6 is supported on a base BP via vibration isolators 89. The substrate stage base plate 6, main columns 9, and base BP (floor) are vibrationally isolated by the vibration isolators 89 so that vibration of the base BP (floor) and main columns 9 is not transmitted to the substrate stage base plate 6 that supports the substrate stage PST.

By the driving of a substrate stage drive apparatus PSTD that contains linear motors and that is controlled by the control apparatus CONT, the substrate stage PST is capable of two-dimensional movement within the XY plane and micro-rotation in the θZ direction on the substrate stage base plate 6 in a state where the substrate P is held via the substrate holder PH. Furthermore, the substrate stage PST can also move in the Z axial direction, the θX direction, and the θY direction. Accordingly, the surface of the substrate P held by the substrate stage PST can move with six degrees of freedom, i.e., in the X axial, Y axial, Z axial, θX, θY, and θZ directions. The moving mirror 83 is provided on the lateral face of the substrate stage PST. In addition, the laser interferometer 84 is provided at a prescribed position relative to the substrate stage PST. The two-dimensional position and the rotational angle of the substrate P on the substrate stage PST are measured in real time by the laser interferometer 84 using the moving mirror 83. Moreover, although not illustrated in the drawing, the exposure apparatus EX is provided with a focus and level detection system that detects the surface position information of the surface of the substrate P held by the substrate stage PST.

The measurement results of the laser interferometer 84 and the detection results of the focus and level detection system are outputted to the control apparatus CONT. Based on the detection results of the focus and level detection system, the control apparatus CONT drives the substrate stage drive apparatus PSTD, controls the focus position (Z position) and inclination angle (θX, θY) of the substrate P, adjusts the positional relation of the surface of the substrate P and the image plane formed via the projection optical system PL and the liquid LQ, and conducts positional control in the X axial direction, Y axial direction, and θZ direction of the substrate P based on the measurement results of the laser interferometer 84.

The liquid supply apparatus 11 of the liquid immersion mechanism 1 is provided with a tank housing the liquid LQ, a pressure pump, a temperature adjustor that adjusts the temperature of the liquid LQ that is supplied, a filter unit that removes foreign matter in the liquid LQ, and so on. One end of the supply tube 13 is connected to the liquid supply apparatus 11, and the other end of the supply tube 13 is connected to the nozzle member 70. The liquid supply operations of the liquid supply apparatus 11 are controlled by the control apparatus CONT. Furthermore, it is not necessary that the exposure apparatus EX be provided without exception with the tank, pressure pump, temperature adjustor, filter unit and so on of the liquid supply apparatus 11, for equipment of the factory or the like where the exposure apparatus EX is installed may be used instead.

A liquid volume controller 19 called a mass flow controller that controls the liquid volume per unit time supplied to the image plane side of the projection optical system PL is provided at a midway point of the supply tube 13. Control of the liquid supply volume by the liquid volume controller 19 is conducted based on command signals of the control apparatus CONT.

The liquid recovery apparatus 21 of the liquid immersion mechanism 1 is provided with a vacuum system including a vacuum pump or the like, a gas-liquid separator that separates the liquid LQ and gas that are recovered, a tank that houses the recovered liquid LQ, and so on. One end of the recovery tube 23 is connected to the liquid recovery apparatus 21, and the other end of the recovery tube 23 is connected to the nozzle member 70. The liquid recovery operations of the liquid recovery apparatus 21 are controlled by the control apparatus CONT. Furthermore, it is not necessary that the exposure apparatus be provided without exception with the vacuum system, gas-liquid separator, tank, and so on of the liquid recovery apparatus 21, for equipment of the factory or the like where the exposure apparatus EX is installed may be used instead.

The nozzle member 70 is supported by support mechanisms 91. The support mechanisms 91 are connected to the lower steps 8 of the main columns 9. The main columns 9 that support the nozzle member 70 via the support mechanisms 91 and the lens barrel base plates 5 that support the lens barrel PK of the projection optical system PL via the flange PF are vibrationally separated via the vibration isolators 87. Accordingly, transmission of vibration incurred by the nozzle member 70 to the projection optical system PL is prevented. In addition, the main columns 9 and the substrate stage base plate 6 that supports the substrate stage PST are vibrationally separated via the vibration isolators 89. Accordingly, transmission of vibration incurred by the nozzle member 70 to the substrate stage PST via the main columns 9 and base BP is prevented. Moreover, the main columns 9 and the mask stage base plate 2 that supports the mask stage MST are vibrationally separated via the vibration isolators 86. Accordingly, transmission of vibration incurred by the nozzle member 70 to the mask stage MST via the main columns 9 is prevented.

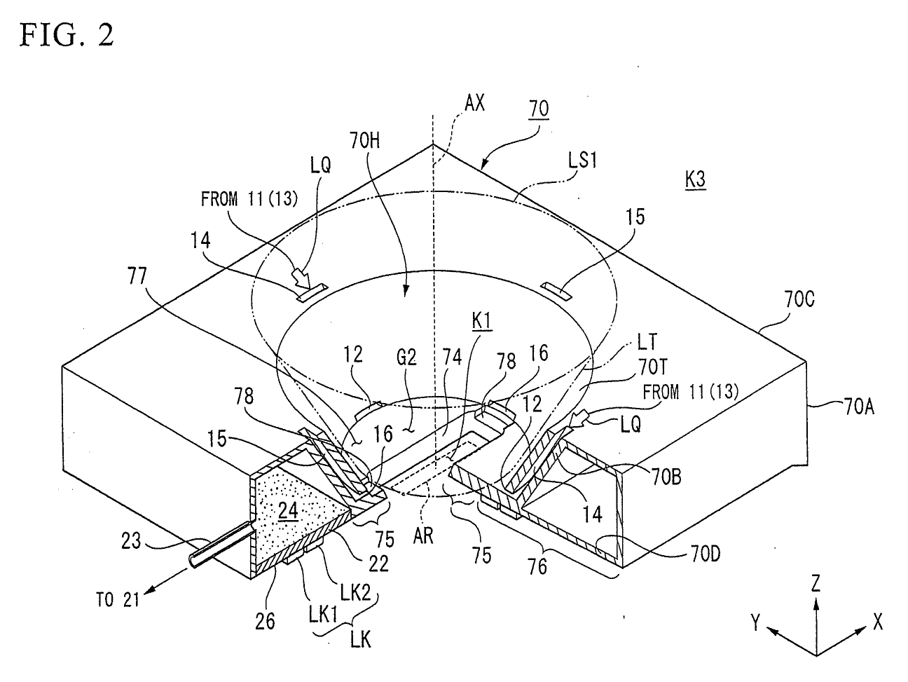

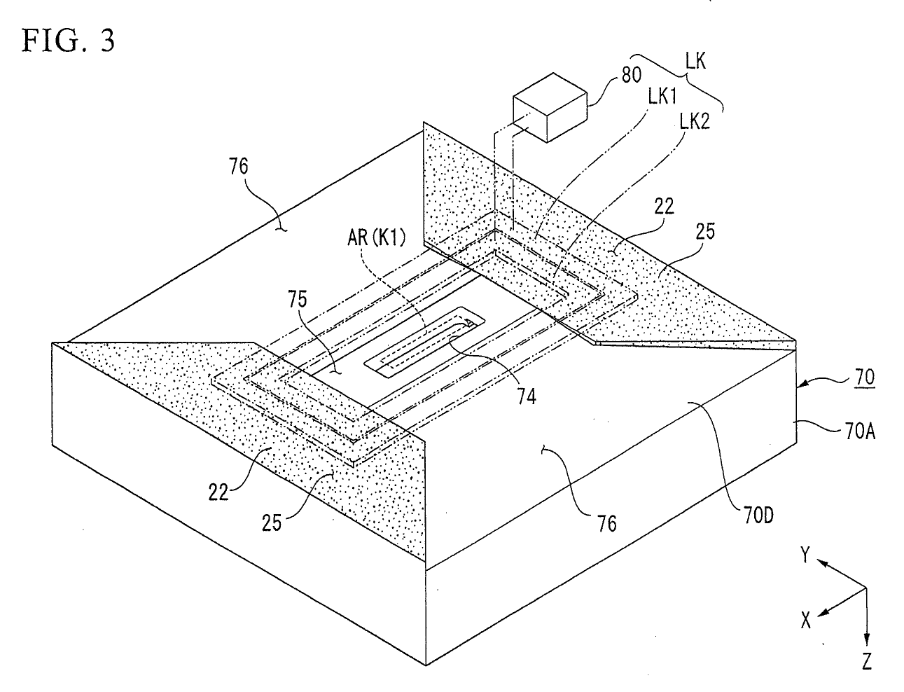

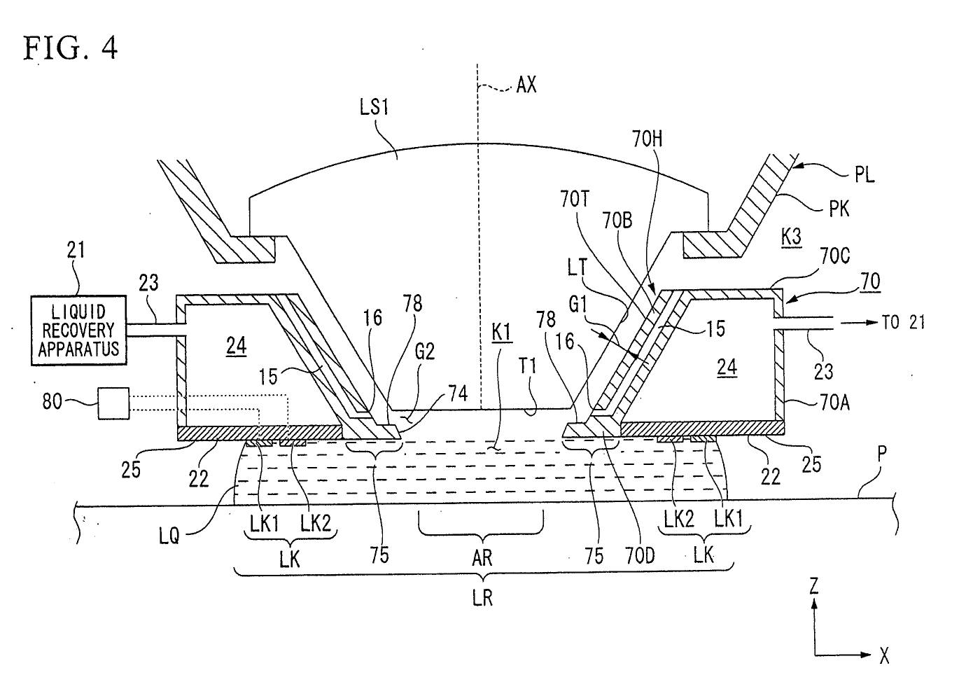

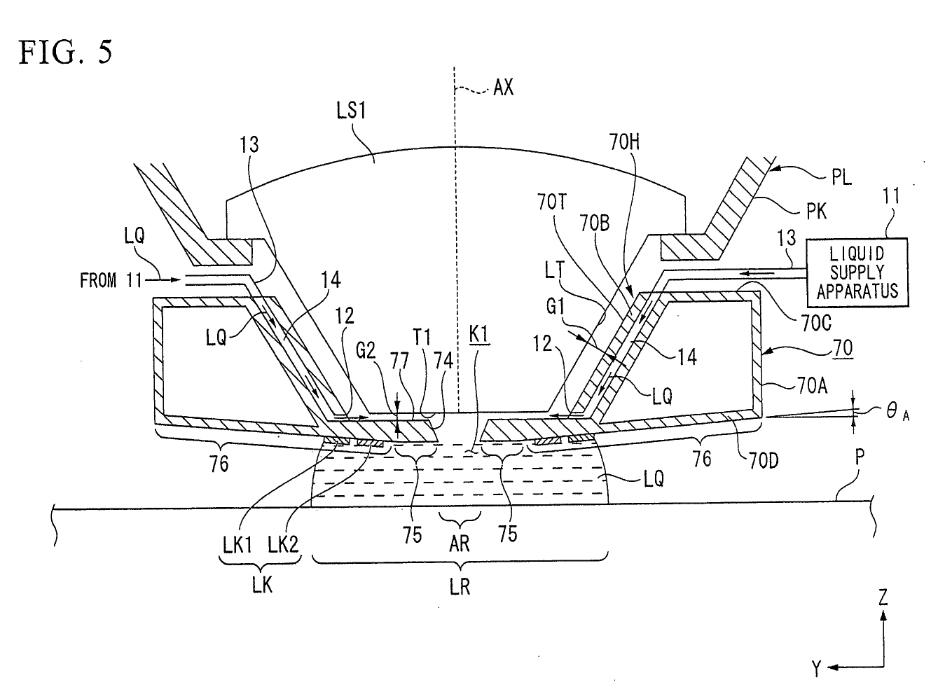

Next, the nozzle member 70 is described with reference to FIG. 2 to FIG. 5. FIG. 2 is a partial, broken, schematic, oblique view that shows the vicinity of a nozzle member 70; FIG. 3 is an oblique view that shows the nozzle member 70 from the underside; FIG. 4 is a lateral cross-sectional view that is parallel to the XZ plane; and FIG. 5 is a lateral cross-sectional view that is parallel to the YZ plane.

The nozzle member 70 is provided in the vicinity of the last optical element LS1 that is closest to the image plane of the projection optical system PL. The nozzle member 70 is an annular member which is provided so that it surrounds the last optical element LS1 above the substrate P (substrate stage PST), and has an aperture 70H at its center in which the projection optical system PL (last optical element LS1) can be disposed. The substrate P (the substrate stage 4) is capable of moving below the nozzle member 70. In addition, the nozzle member 70 of the present embodiment has electrodes (electrostatic holders) LK1 and LK2 (discussed below) which configure the liquid holding apparatus LK that holds the liquid LQ by electrostatic force in the liquid immersion region LR between the nozzle member 70 and the substrate P.

In the present embodiment, the nozzle member 70 is configured from the combination of a plurality of members, and the external form of the nozzle member 70 is approximately square-shaped from a planar view. Furthermore, the nozzle member 70 may be composed of a single material (titanium, etc.), and may be composed of, for example, aluminum, titanium, stainless steel, duralumin, and alloys containing these.

The nozzle member 70 has side plates 70A, an inclined plate 70B, a ceiling plate 70C provided at the top ends of the side plates 70A and inclined plate 70B, and a bottom plate 70D that opposes the substrate P (substrate stage PST). The inclined plate 70B is formed in a conical shape, and the last optical element LS1 is disposed on the inner side of the aperture 70H formed by the inclined plate 70B. The inner side face 70T of the inclined plate 70B (i.e., the inner side face of the aperture 70H of the nozzle member 70) and the side face LT of the last optical element LS1 of the projection optical system PL are mutually opposite, and a prescribed gap G1 is provided between the inner side face 70T of the inclined plate 70B and the side face LT of the last optical element LS1. By providing the gap G1, direct transmission of vibration incurred by the nozzle member 70 to the projection optical system PL (last optical element LS1) is prevented. Moreover, the inner side face 70T of the inclined plate 70B has liquid repellency (water repellency) relative to the liquid LQ, inhibiting infiltration of the liquid LQ into the gap G1 between the side face LT of the last optical element LS1 of the projection optical system PL and the inner side face 70T of the inclined plate 70B. Furthermore, as liquid repellency treatment for imparting liquid repellency to the inner side face 70T of the inclined plate 70B, one may cite, for example, treatment that causes adhesion of liquid-repellent material such as fluororesin material such as polytetrafluoroethylene (Teflon (registered trademark)), acrylic resin material, silicon resin material, and so on.

A portion of the bottom plate 70D is provided between a lower surface T1 of the last optical element LS1 of the projection optical system PL and the substrate P (substrate stage PST) in the Z axial direction. At the center of the bottom plate 70D, an opening 74 is formed through which the exposure light EL passes. The opening 74 is constituted so as to allow passage of the exposure light EL that has transited the last optical element (optical member) LS1 of the projection optical system PL. In the present embodiment, the projection region AR irradiated by the exposure light EL is provided in the shape of a slit (an approximately rectangular shape) with the X axial direction (non-scanning direction) as the longitudinal direction. The opening 74 has a shape that corresponds to the projection region AR, and is formed in the shape of a slit (an approximately rectangular shape) with the X axial direction (non-scanning direction) as the longitudinal direction. The opening 74 is formed larger than the projection region AR, and the exposure light EL that transits the projection optical system PL is able to arrive onto the substrate P without being blocked by the bottom plate 70D.

The lower surface of the nozzle member 70 that opposes the substrate P (substrate stage PST) has a first region 75 which is disposed at a position that can be irradiated with the exposure light EL and that opposes the surface of the substrate P. The first region 75 is a flat surface that is parallel to the XY plane. The first region 75 is provided so that it surrounds the optical path space K1 (projection region AR) of the exposure light EL. That is, the first region 75 is a face that is provided at the perimeter of the opening 74 of the bottom plate 70D through which the exposure light EL transits. Here, the position that is irradiable with the exposure light EL includes a position that opposes the projection optical system PL. As the first region 75 is provided so that it surrounds the optical path space K1 of the exposure light EL that transits the projection optical system PL, the control apparatus CONT is able to have the first region 75 and the surface of the substrate P face each other by disposing the substrate P at a position that is irradiable with the exposure light EL.

As the surface of the substrate P held by the substrate stage PST is approximately parallel to the XY plane, the first region 75 of the nozzle member 70 is configured to be provided so that it is opposite the surface of the substrate P that is held by the substrate stage PST, and so that it is approximately parallel to the surface (XY plane) of the substrate P. In the below description, the first region (flat surface) 75 of the nozzle member 70—which is provided so as to be opposite the surface of the substrate P and so as to surround the optical path space K1 of the exposure light EL, and which is formed so as to be approximately parallel with the surface (XY plane) of the substrate P—is properly called a “first land surface 75.”

Of the nozzle member 70, the first land surface 75 is provided so as to be at the position which is closest to the substrate P that is held by the substrate stage PST. That is, the first land surface 75 is the portion where the gap with the surface of the substrate P that is held by the substrate stage PST is smallest. By this means, it is possible to satisfactorily hold the liquid LQ between the first land surface 75 and the substrate P, and form the liquid immersion region LR.

The first land surface 75 is provided so that it surrounds the optical path space K1 (projection region AR) of the exposure light EL between the substrate P and the lower surface T1 of the projection optical system PL. As stated above, the first land surface 75 is provided in a portion of the region of the lower surface of the bottom plate 70D, and is configured to be provided at the perimeter of the opening 74 so that it surrounds the opening 74 through which the exposure light EL passes. The first land surface 75 has a shape that corresponds to the opening 74, and the external shape of the first land surface in the present embodiment is rectangularly formed with the X axial direction (non-scanning direction) as the longitudinal direction.

The distance between the surface of the substrate P and the lower surface T1 of the last optical element LS1 is longer than the distance between the surface of the substrate P and the land surface 75. That is, the lower surface T1 of the last optical element LS1 is formed at a higher position than the first land surface 75. Moreover, the bottom plate 70D is provided so that the lower surface T1 of the last optical element LS1 does not contact the substrate P (substrate stage PST). As shown in FIG. 5, a space with a prescribed gap G2 is formed between the lower surface T1 of the last optical element LS1 and the upper surface 77 of the bottom plate 70D. The upper surface 77 of the bottom plate 70D is provided at the perimeter of the opening 74 so as to surround the opening 74 through which the exposure light EL passes. That is, the upper surface 77 of the bottom plate 70D is provided so that it surrounds the optical path space K1 of the exposure light EL, and is configured to face the last optical element LS1 with interposition of a prescribed gap G2. In the below description, a space on the inner side of the nozzle member 70 that includes the space between the lower surface T1 of the last optical element LS1 and the upper surface 77 of the bottom plate 70D is properly called an “internal space G2.”

The lower surface of the nozzle member 70 has second regions 76, which are provided on the outer side of the first land surface 75 relative to the optical path space K1 of the exposure light EL in the Y axial directions so as to face the surface of the substrate P that is held by the substrate stage PST and that is disposed at a position that is irradiable with the exposure light EL, and which are provided at positions that are farther from the surface of the substrate P than the first land surface 75. In the below description, the second regions 76 of the nozzle member 70, which are provided on the outer side of the first land surface 75 relative to the optical path space K1 of the exposure light EL in the Y axial directions so as to face the surface of the substrate P, and which are provided at positions that are farther from the surface of the substrate P than the first land surface 75 are properly called “second land surfaces 76.”

The second land surfaces 76 of the present embodiment have sloped surfaces such that their interstice with the substrate P increases as their distance from the optical path space K1 of the exposure light EL increases in the Y axial directions. The second land surfaces 76 are respectively provided on one side (+Y side) and the other side (−Y side) of the scanning direction relative to the first land surface 75. As the surface of the substrate P held by the substrate stage PST is approximately parallel with the XY plane, the second land surfaces 76 of the nozzle member 70 are provided and configured so as to face the substrate P that is held by the substrate stage PST, and so as to be inclined relative to the surface (XY plane) of the substrate P.

Portions of the first land surface 75 and second land surfaces 76 are contacted by the liquid LQ that forms the liquid immersion region LR, and the lower surface T1 of the last optical element LS1 is also contacted by the liquid LQ that fills the optical path space K1. That is, the first land surface 75 and second land surfaces 76 of the nozzle member 70, and lower surface T1 of the last optical element LS1 respectively constitute liquid contact surfaces that contact the liquid LQ.

As mentioned below, the first land surface 75 and second land surfaces 76 are provided in a prescribed positional relation so that the liquid LQ that exists between the surface of the substrate P and the second land surfaces 76 does not separate from the second land surfaces 76, in the case where the liquid LQ exists between the surface of the substrate P and the second land surfaces 76. Specifically, even if the substrate P is moved in a state where the optical path space K1 is filled with the liquid LQ, the second land surfaces 76 are formed so that the liquid LQ that exists between the surface of the substrate P and the second land surfaces 76 does not separate from (i.e., does not come apart from) the second land surfaces 76.

In the present embodiment, the second land surfaces 76 are continuously provided relative to the first land surface 75. That is, the −Y side edge of the second land surface 76 that is provided on the +Y side of the optical path space K1, which is the edge that is closest to the optical path space K1 of the exposure light EL, and the +Y side edge of the first land surface 75 are provided at approximately the same position (height) with respect to the substrate P; furthermore, the +Y side edge of the second land surface 76 that is provided on the −Y side of the optical path space K1, which is the edge that is closest to the optical path space K of the exposure light EL, and the −Y side edge of the first land surface 75 are provided at approximately the same position (height) with respect to the substrate P. The angles θA constituted by the first land surface 75 and second land surfaces 76 are set to 10° or less (see FIG. 5). In the present embodiment, the angles θA constituted by the first land surface 75 (XY plane) and second land surfaces 76 are set to approximately 4°.

The first land surface 75 and second land surfaces 76 are each lyophilic relative to the liquid LQ. Moreover, the contact angle of the first land surface 75 and the liquid LQ, and the contact angles of the second land surfaces 76 and the liquid LQ are approximately equal. In the present embodiment, the bottom plate 70D that forms the first land surface 75 and second land surfaces 76 is formed from titanium. Furthermore, it is also acceptable to subject the first land surface 75 and second land surfaces 76 to surface treatment (lyophilicizing treatment) that imparts lyophilicty relative to the liquid LQ.

As shown in FIG. 2 through FIG. 5, the aforementioned liquid holding apparatus LK is configured from electrodes LK1 and LK2 that are provided on the bottom plate 70D of the nozzle member 70 and that have mutually different polarities, and an applicator 80 that applies a prescribed voltage to these electrodes LK1 and LK2 (see FIG. 3 and FIG. 4). Operation of the applicator 80 is controlled by the aforementioned control apparatus CONT. As shown in FIG. 4 and FIG. 5, the electrode LK1 is disposed at the edge of the liquid immersion region LR, and is set as the cathode in the present embodiment. The electrode LK2 is disposed with some separation from the electrode LK1 more toward the inner side (optical axis side of the projection optical system PL) than the electrode LK1, and is set as the anode in the present embodiment.

In addition, the nozzle member 70 is provided with supply ports 12 which supply the liquid LQ that serves to fill the optical path space K1 of the exposure light EL, and recovery ports 22 which recover the liquid LQ that serves to fill the optical path space K1 of the exposure light EL. The nozzle member 70 is further provided with supply channels 14 that connect to the supply ports 12, and recovery channels 24 that connect to the recovery ports 22. In FIG. 2 to FIG. 5, although illustration thereof is either omitted or simplified, the supply channels 14 connect to the other end of supply tubes 13, and the recovery channels 24 connect to the other end of recovery tubes 23.

As shown in FIG. 2 and FIG. 5, the supply channels 14 are formed by slit-shaped through-holes which pass through the interior of the inclined plate 70B of the nozzle member 70 in the direction of inclination. In the present embodiment, the supply channels 14 are respectively provided on both sides of the optical path space K1 (projection region AR) in the Y axial directions. The upper end of each supply channel (through-hole) 14 is connected to the other end of the respective supply tube 13, thereby connecting the supply channels 14 to the liquid supply apparatus 11 via the supply tubes 13. On the other hand, the lower end of each supply channel 14 is provided in the vicinity of the internal space G2 between the lower surface T1 of the last optical element LS1 and the upper surface 77 of the bottom plate 70D, and this lower end of each supply channel 14 constitutes the respective supply port 12.

The supply ports 12 are designed to supply the liquid LQ that serves to fill the optical path space K1. The liquid LQ from the liquid supply apparatus 11 is supplied to the supply ports 12, and the supply ports 12 are capable of supplying the liquid LQ between the lower surface T1 of the last optical element LS1 and the upper surface 77 of the bottom plate 70D, i.e., to the internal space G2. By supplying the liquid LQ from the supply ports 12 to the internal space G2 between the last optical element LS1 and the bottom plate 70D, the optical path space K1 of the exposure light EL between the last optical element KS1 and the substrate P is filled with the liquid LQ.

In addition, as shown in FIG. 2 and FIG. 4, the nozzle member 70 has gas discharge ports 16 that are designed to cause communication of the internal space G2 and an external space K3. The gas discharge ports 16 are connected to gas discharge channels 15. The gas discharge channels 15 are formed by slit-shaped through-holes that pass through the interior of the inclined plate 70B of the nozzle member 70 in the direction of inclination.

The nozzle member 70 has spatial regions 24 that open downward between the side plates 70A and the inclined plate 70B. The recovery ports 22 are disposed in the open areas of the spatial regions 24. Moreover, the recovery channels are configured by the spatial regions 24. The other end of each recovery tube 23 connects to a portion of each recovery channel (spatial region) 24. The recovery ports 22 are designed to recover the liquid LQ that serves to fill the optical path space K1.

The nozzle member 70 is provided with porous members 75 that are disposed so as to cover the recovery ports 22, and that have multiple holes. The porous members 25 may be configured from mesh members that have multiple holes. For example, they may be configured from mesh members that form approximately hexagonal honeycomb patterns composed of multiple holes. Moreover, to provide further detail with respect to the electrodes LK1 and LK2 that are provided on the bottom plate 70D of the nozzle member 70, as shown in FIG. 3, they are both formed in mutually independent box-like shapes across the second land surfaces 76 and the porous members 25 (recovery ports 22). They are formed in a longitudinal shape in FIG. 3, but their shape is not limited thereto, and may be appropriately set according to the region in which liquid is to be held. With respect to the electrodes LK1 and LK2, members composing the electrodes may be subjected to adhesive bonding, or they may be formed in the manner of thin film by vapor deposition or the like.

Next, a description is given regarding the method for exposing the substrate P with a pattern image of the mask M using the exposure apparatus EX having the above-described configuration.

In order to fill the optical path space K1 of the exposure light EL with the liquid LQ, the control apparatus CONT respectively drives the liquid supply apparatus 11 and the liquid recovery apparatus 21. Based on the control of the control apparatus CONT, the liquid LQ that is fed from the liquid supply apparatus 11 flows through the supply tubes 13, after which it is supplied from the supply ports 12 to the internal space G2 between the last optical element LS1 of the projection optical system PL and the bottom plate 70D via the supply channels 14 of the nozzle member 70. The liquid LQ supplied from the supply ports 12 to the internal space G2 flows in such a way that it spreads over the upper surface 77 of the bottom plate 70D, and reaches the opening 74. As a result of the supply of the liquid LQ from the supply ports 12 to the internal space G2, gaseous parts existing in the internal space G2 are discharged to the external space K3 via the gas discharge ports 16 and opening 74. Accordingly, it is possible to prevent the inconveniences pertaining to the collection of gas in the internal space G2 when the supply of the liquid LQ to the internal space G2 is started, and it is possible to prevent the inconveniences caused by gaseous parts (air bubbles) in the liquid LQ of the optical path space K1.

After the liquid LQ that is supplied to the internal space G2 has filled the internal space G2, it flows into the space between the first land surface 75 and the substrate P (substrate stage PST) via the opening 74, and fills the optical path space K1 of the exposure light EL. Thus, by supplying the liquid LQ to the internal space G2 from supply ports 12 capable of supplying the liquid LQ to the internal space G2 between the last optical element LS1 and the bottom plate 70D, the optical path space K1 of the exposure light EL between the last optical element LS1 (projection optical system PL) and the substrate P is filled with the liquid LQ.

At this time, the liquid recovery apparatus 21 that is driven based on the control of the control apparatus CONT recovers a prescribed amount of the liquid LQ per unit time. The liquid recovery apparatus 21 that includes a vacuum system is able to recover the liquid LQ existing between the recovery ports 22 (porous members 25) and the substrate P via the recovery ports 22 by creating negative pressure in the spatial regions 24. The liquid LQ that fills the optical path space K1 of the exposure light EL flows into the recovery channels 24 via the recovery ports 22 of the nozzle member 70, and flows through the recovery tubes 23, after which it is recovered by the liquid recovery apparatus 21.

As stated above, the control apparatus CONT uses the liquid immersion mechanism 1 to supply a prescribed amount of the liquid LQ per unit time to the optical path space K1 and to recover a prescribed amount of the liquid LQ of the optical path space K1 per unit time, thereby enabling the optical path space K1 of the exposure light EL between the projection optical system PL and the substrate P to be filled with the liquid LQ, and enabling local formation of the liquid immersion region LR of the liquid LQ on the substrate P.

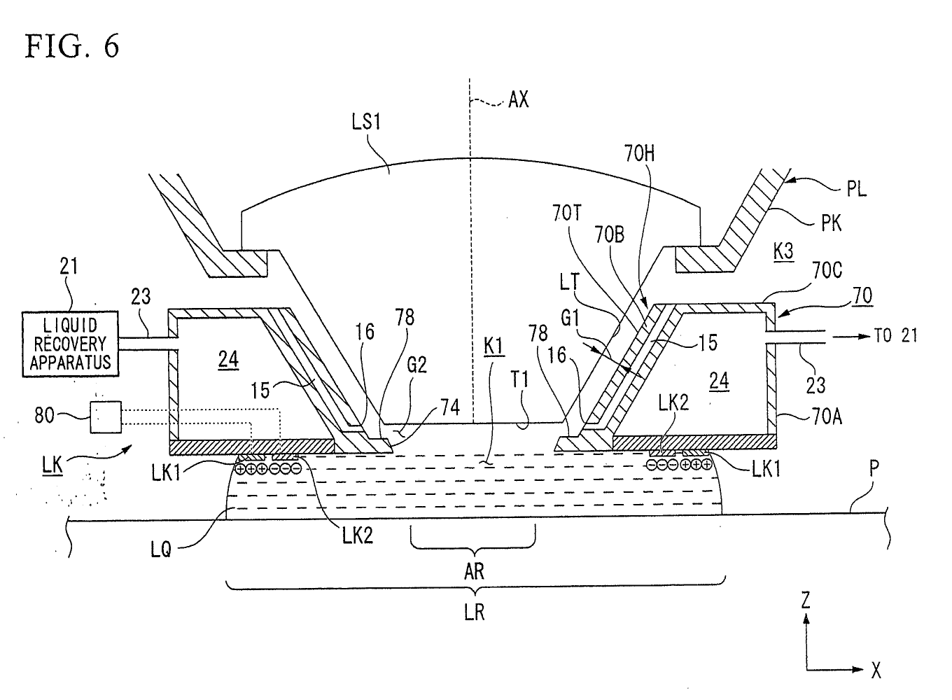

In addition, the control apparatus CONT causes energization of the electrodes LK1 and LK1 via the applicator 80, and establishes the electrode LK1 as the cathode, and the electrode LK2 as the anode. By this means, electrostatic polarization occurs; as shown in FIG. 6, the molecules of the liquid LQ are polarized, and electrical charge polarization occurs. Negative charges collect at the electrode LK2, and positive charges collect at the electrode LK1, with the result that the liquid LQ is held in the liquid immersion region LR between the nozzle member 70 and the substrate P by the electrostatic force between the electrodes LK1 and LK2. During this time, as well, supply operations pertaining to the liquid LQ by the liquid supply apparatus 11 and recovery operations pertaining to the liquid LQ by the liquid recovery apparatus 21 continue, and a flow of the liquid LQ between the two is established. However, as the electrostatic force of the electrodes LK1 and LK2 is operative in addition to a prescribed surface tension, the impetus of the liquid LQ to spread outward beyond the liquid immersion region LR is more intensely inhibited. Moreover, it may happen that the liquid LQ recovered by the recovery ports 22 (porous members 25) is in a charged state. Consequently, it would be advisable to have it fed to the liquid recovery apparatus 21 after transiting a static charge eliminator (not illustrated in the drawings) or the like.

In a state where the optical path space K1 of the exposure light EL is filled with the liquid LQ, the control apparatus CONT projects a pattern image of the mask M onto the substrate P via the projection optical system PL and the liquid LQ of the optical path space K1 while causing relative movement of the projection optical system PL and the substrate P. As stated above, as the exposure apparatus EX of the present embodiment is a scanning type exposure apparatus that sets the scanning direction in the Y axial directions, the control apparatus CONT irradiates the substrate P with the exposure light EL while moving the substrate P in the Y axial directions at a speed of, for example, 500-700 mm/sec by controlling the substrate stage PST, and exposes the substrate P.

In such a scanning type exposure apparatus, due to the structure of the nozzle member, it is possible in conjunction with, for example, an increase in the scanning speed (moving speed) of the substrate P that the liquid LQ may not be sufficiently recovered via the recovery ports 22, and that the liquid LQ that fills the optical path space K1 may leak outward beyond the space between the substrate P and the nozzle member 70. In the present embodiment, however, the liquid LQ is not only held in the liquid immersion region LR by the surface tension of the liquid LQ, but also by the electrostatic force of the electrodes LK1 and LK2.

As stated above, in the present embodiment, as the liquid LQ is held with electrostatic force by the liquid holding apparatus LK, the optical path space K1 of the exposure light EL can be filled in a desired state with the liquid LQ without leakage of the liquid LQ even when the substrate P is being exposed during movement, with the result that it is possible to prevent a deterioration in exposure accuracy and measurement accuracy via the liquid LQ. Accordingly, in the present embodiment, it is also possible to further increase the moving speed (scanning speed) of the substrate P, improve through-put, and raise productivity.

### Second Embodiment

Next, a second embodiment of the liquid holding apparatus and exposure apparatus is described.

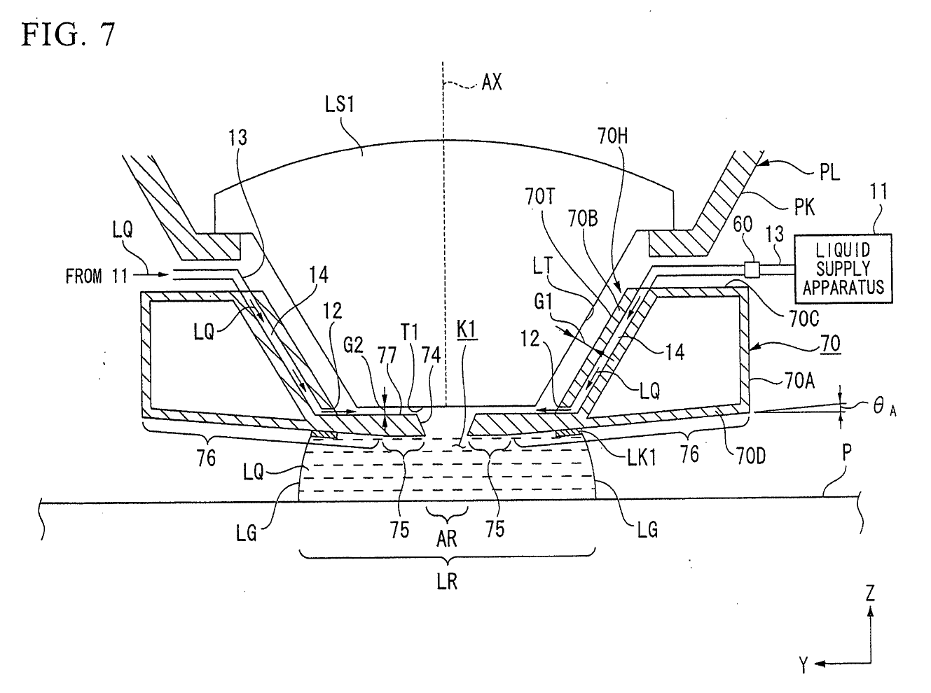

FIG. 7 is a schematic block diagram of an exposure apparatus provided with the liquid holding apparatus LK pertaining to the second embodiment. In this drawing, constituent parts that are identical to those in the first embodiment that are shown in FIG. 1 to FIG. 6 are assigned identical symbols, and description thereof is omitted.

The liquid holding apparatus LK that is shown in FIG. 7 includes: the electrode LK1 provided on the bottom plate 70D of the nozzle member 70; the applicator 80 (not illustrated in FIG. 7; see FIG. 3 and FIG. 4) that applies a prescribed voltage to the electrode LK1; and charging apparatuses 60 which are provided in the supply tubes 13 of the liquid supply apparatus 11 and which charge the liquid LQ that is supplied to the nozzle member 70 with a positive charge. The liquid LQ that is charged by the charging apparatuses 60 is supplied to the supply ports 12 via the supply tubes 13 and supply channels 14. The liquid LQ that is supplied to the supply ports 12 is supplied to the optical path space K1 from the supply ports 12. Thus, the charging apparatuses 60 charge the liquid LQ prior to its supply to the optical path space K1 from the supply ports 12. Disposed at a position which contacts the liquid LQ of the liquid immersion space (liquid immersion region LR) that is filled with the liquid LQ, the electrode LK1 surrounds the optical path space K1 of the exposure light EL between the last optical element LS1 and the substrate P.

The remaining configuration is identical to that of the aforementioned first embodiment.

In the exposure apparatus EX of the foregoing configuration, the liquid LQ that is supplied to the nozzle member 70 from the liquid supply apparatus 11 fills the optical path space K1 in a positively charged state, and is able to locally form the liquid immersion region LR of the liquid LQ on the substrate P. At this time, positive charges collect at the electrode LK1 that has been energized and made cathodic via the applicator 80 under the control of the control apparatus CONT, with the result that the liquid LQ is held in the liquid immersion region LR between the nozzle member 70 and the substrate P by the electrostatic force between the liquid LQ and the electrode LK1.

Thus, by means of the electrode LK1 that is charged with a polarity that differs from that of the liquid LQ of the liquid immersion space when the liquid LQ is charged to a prescribed polarity, it is possible to satisfactorily hold the liquid LQ between the nozzle member 70 and the substrate P, and to set the state of the interface (meniscus, edge) LG of the liquid LQ of the liquid immersion space to a prescribed state. The interface LG of the liquid LQ of the liquid immersion space includes the interface of the liquid immersion space (liquid space) and the gaseous space on its outer side.

The state of the interface LG includes the position of the interface LG in the XY directions between the surface of the substrate P and the lower surface of the nozzle member 70 that opposes the surface of the substrate P. The lower surface of the nozzle member 70 includes the first land surface 75, second land surfaces 76, and lower surfaces of the porous members 25. Moreover, the state of the interface LG includes the shape of the interface LG. In addition, the state of the interface LG includes the contact angle θ of the surface of the substrate P and the liquid LQ.

Thus, even with the present embodiment, it is possible to obtain the same actions and effects as with the aforementioned first embodiment. In the present embodiment, by means of the liquid LQ that is charged by a positive electrode, it is possible to set the state of the interface LG to a desired state, and to satisfactorily hold the liquid LQ. As with the first embodiment, in the case also of the present embodiment, it may happen that the liquid LQ recovered by the recovery ports 22 (porous members 25) is in a charged state. Consequently, it is advisable to have it fed to the liquid recovery apparatus 21 after transiting a static charge eliminator (not illustrated in the drawings) or the like.

While preferred embodiments of the present invention have been described above with reference to appended drawings, it should be understood that these are not to be considered as limiting. The various forms, combinations and the like of the respective components that are shown in the above-described embodiments are exemplary, and a variety of modifications based on design requirements and the like can be made without departing from the spirit or scope of the present invention.

For example, in the aforementioned first embodiment, it was explained that the electrode LK1 disposed at the edge of the liquid immersion region LR is the cathode, and that the electrode LK2 disposed on the inner side is the anode, but it is also acceptable to have a configuration where the electrode LK1 is the anode, and the electrode LK2 is the cathode.

Similarly, in the aforementioned second embodiment, a configuration was adopted where the electrode LK1 is a cathode, and the charging apparatus 60 charges the liquid LQ with positive charge, but it is also acceptable to have a configuration where the electrode LK1 is an anode, and the charging apparatus 60 charges the liquid LQ with negative charge.

Moreover, in the aforementioned embodiments, the descriptions concerned a configuration where the liquid immersion region LR is provided between the nozzle member 70 and the substrate P, but one is not limited thereto, and it is also acceptable to adopt a configuration where it is provided between the nozzle member 70 and the substrate stage PST.

In addition, in the aforementioned embodiments, a configuration was adopted where the liquid holding apparatus LK is applied to the exposure apparatus EX, but it is also possible to make various applications to other devices that hold liquid in a fixed region.

In the present embodiment, pure water is used as the liquid LQ. Pure water is advantageous, because it can be easily obtained in large quantities at, for example, semiconductor fabrication plants, and does not adversely affect the photoresist on the substrate P, the optical elements (lenses), and so on. In addition, as pure water does not adversely effect the environment, and as its impurity content is extremely low, one may anticipate a cleaning effect with respect to the surface of the substrate P and the surfaces of the optical elements provided on the distal face of the projection optical system PL. Furthermore, in cases where the purity of pure water supplied from the plant or the like is low, it is also acceptable to provide the exposure apparatus with an ultrapure water production device.

The refractive index n of pure water (water) relative to exposure light EL that has a wavelength on the order of 193 nm is said to be approximately 1.44. When ArF excimer laser light (wavelength: 193 nm) is used as the light source of the exposure light EL, wavelength is shortened to 1/n—i.e., to approximately 134 nm—and a high resolution is obtained on the substrate P. Furthermore, as depth of focus is enlarged approximately n-fold—i.e., approximately 1.44 times—compared to in the open air, when it is sufficient if depth of focus is maintained on the same level as in the case of use in the open air, it is possible to further increase the numerical aperture of the projection optical system PL, and resolution is enhanced in this respect as well.

### Third Embodiment

Next, a third embodiment is described. In the below description, constituent parts that are identical or equivalent to those in each of the foregoing embodiments are assigned identical symbols, and description thereof is abbreviated or omitted.

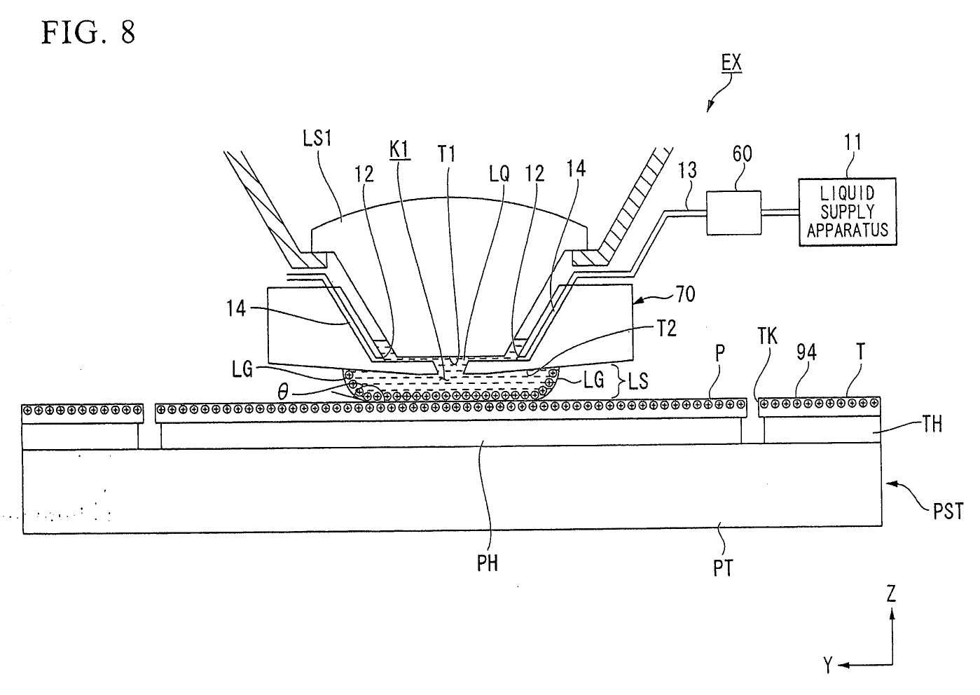

FIG. 8 is a schematic drawing that shows a portion of the exposure apparatus EX of the third embodiment. As with each of the foregoing embodiments, the nozzle member 70 is provided with a first land surface 75, second land surfaces 76, and lower surfaces of the porous members 25, which are capable of facing the surface of the substrate P. The nozzle member 70 is capable of holding the liquid LQ between the surface of the substrate P and the first land surface 75, second land surfaces 76, and porous members 25.

In the below description, the first land surface 75, second land surfaces 76, and lower surfaces of the porous members 25 of the nozzle member 70—which are capable of opposing the surface of the substrate P, and which are capable of holding the liquid LQ between themselves and the surface of the substrate P—are properly and collectively called the “lower surface T2 of the nozzle member 70.”

Furthermore, although the nozzle member 70 is illustrated in a simplified manner in FIG. 8, it has the same structure as the nozzle member 70 described in each of the foregoing embodiments.

The liquid LQ that is supplied to the optical path space K1 from the supply ports 12 is held between the lower surface T1 of the last optical element LS1 and lower surface T2 of the nozzle member 70 and the surface of the substrate P that opposes these lower surfaces T1 and T2. That is, the last optical element LS1 that has the lower surface T1 and the nozzle member 70 that has the lower surface T2 hold the liquid LQ between themselves and the surface of the substrate P that opposes these lower surfaces T1 and T2, and are capable of forming the liquid immersion space LS of the liquid LQ between themselves and the surface of the substrate P.

In the present embodiment, the liquid immersion space LS is a space (liquid space) that is filled with the liquid LQ. Furthermore, the liquid immersion region LR described in each of the foregoing embodiments includes the region that is occupied by the liquid immersion space LS within the XY plane that is approximately parallel to the surface of the substrate P.

Moreover, the last optical element LS1 and the nozzle member 70 are capable of forming the liquid immersion space LS not only between themselves and the surface of the substrate P, but also between themselves and an object which is capable of movement to a position that is irradiable with the exposure light EL from the last optical element LS1. An object which is capable of movement to a position that is irradiable with the exposure light EL from the last optical element LS1 includes an object which is capable of movement to a position that opposes the lower surface T1 of the last optical element LS1 and the lower surface T2 of the nozzle member 70. An object which is capable of movement to a position that opposes the lower surface T1 of the last optical element LS1 and the lower surface T2 of the nozzle member 70 includes the substrate stage PST which can be moved while holding the substrate P that is irradiated with the exposure light EL.

The last optical element LS1 and the nozzle member 70 are capable of holding the liquid LQ between themselves and either the upper surface 94 of the substrate stage PST or the surface of the substrate P held by the substrate stage PST which is capable of movement to a position that opposes the lower surface T1 of the last optical element LS1 and the lower surface T2 of the nozzle member 70. The last optical element LS1 and the nozzle member 70 are capable of forming the liquid immersion space LS between the lower surface T1 and the lower surface T2 and either the upper surface 94 of the substrate stage PST or the surface of the substrate P.

In the present embodiment, the substrate stage PST includes a stage body PT, a substrate holder PH that is disposed on the stage body PT and that removably holds the substrate P, and a plate member holder TH that is disposed at the perimeter of the substrate holder PH and that removably holds a plate member T. The plate member T has an opening TK in which the substrate P can be disposed. The plate member T that is held by the plate member holder TH is disposed at the perimeter of the substrate P so as to surround the substrate P that is held by the substrate holder PH. In the present embodiment, the upper surface 94 of the substrate stage PST includes the upper surface of the plate member T.

In the present embodiment, the inner surface of the opening TK of the plate member T that is held by the plate member holder TH and the outer surface of the substrate P that is held by the substrate holder PH are disposed so as to oppose each other with interposition of a prescribed gap. The plate member holder TH holds the plate member T so that the XY plane and the upper surface 94 of the plate member T are approximately parallel. The substrate holder PH holds the substrate P so that the XY plane and the surface of the substrate P are approximately parallel. Moreover, in the present embodiment, the upper surface 94 of the plate member T that is held by the plate member holder TH and the surface of the substrate P that is held by the substrate holder PH are disposed within approximately the same plane (flush with each other).

In the below description, for purposes of simplification, description is mainly given for the case where the substrate P that is held by the substrate stage PST is disposed at a position that opposes the lower surface T1 of the last optical element LS1 and the lower surface T2 of the nozzle member 70.

Moreover, in the below description, the case is described where the liquid LQ contains decalin (C₁₀H₁₈). Decalin (decahydronaphthalene) has a higher refractive index relative to the exposure light EL (in this embodiment, ArF excimer laser light) than water (pure water). The refractive index of pure water (water) relative to exposure light EL (ArF excimer laser light) that has a wavelength on the order of 193 nm is said to be approximately 1.44. The refractive index of decalin is said to be approximately 1.60. Consequently, by using decalin as the liquid LQ, it is possible to substantially shorten exposure light wavelength and enhance resolution and to substantially enlarge depth of focus compared to the case where water (pure water) is used as the liquid LQ.

In FIG. 8, the exposure apparatus EX of the present embodiment includes: the last optical element LS1 which has the lower surface T1 and which is capable of forming the liquid immersion space LS with the surface of the substrate P that opposes the lower surface T1; the nozzle member 70 which has the lower surface T2 and which is capable of forming the liquid immersion space LS with the surface of the substrate P that opposes the lower surface T2; and the supply ports 12 which supply the liquid LQ for forming the liquid immersion space LS to the optical path space K1 of the exposure light EL between the last optical element LS1 and the substrate P. The supply ports 12 are disposed in the nozzle member 70. The optical path space K1 is filled with the liquid LQ of the liquid immersion space LS. The exposure apparatus EX exposes the substrate P via the liquid LQ of the liquid immersion space LS.

In order to establish the state of the interface LG of the liquid immersion space LS in a prescribed state, the exposure apparatus EX forms the liquid immersion space LS with the liquid LQ that is charged to a prescribed polarity. In the present embodiment, the liquid LQ is charged before it is supplied to the optical path space K1 from the supply ports 12.

As in the above-described second embodiment, the exposure apparatus EX of the present embodiment is provided with charging apparatuses 60 that charge the liquid LQ to the prescribed polarity. The charging apparatuses 60 charge the liquid LQ to the prescribed polarity before it is supplied to the optical path space K1 from the supply ports 12.

The charging apparatuses 60 are provided in the supply tubes 13 that are connected to the supply ports 12. The liquid LQ that is fed from the liquid supply apparatus 11 is supplied to the charging apparatuses 60. After charging the liquid LQ from the liquid supply apparatus 11 to the prescribed polarity, the charging apparatuses 60 feed the liquid LQ to the supply ports 12 via the supply tubes 13 and the supply channels 14. That is, the liquid LQ charged to the prescribed polarity by the charging apparatuses 60 is supplied to the supply ports 12 via the supply tubes 13 and the supply channels 14. The liquid LQ supplied to the supply ports 12 is supplied to the optical path space K1 from the supply ports 12.

In the present embodiment, the state of the interface (meniscus, edge) LG of the liquid LQ of the liquid immersion space LS is set to a prescribed state by the liquid LQ that has been charged to the prescribed polarity. The interface LG of the liquid LQ of the liquid immersion space LS includes the interface of the liquid immersion space (liquid space) LS and the gaseous space on its outer side.

The state of the interface LG includes the position of the interface LG in the XY directions between the surface of the substrate P and the lower surface T2 of the nozzle member 70 that opposes the surface of the substrate P. Moreover, the state of the interface LG includes the shape of the interface LG. In addition, the state of the interface LG includes the contact angle θ of the surface of the substrate P and the liquid LQ.

In the present embodiment, in order to set the state of the interface LG to the prescribed state, the surface of the substrate P is charged to the same polarity as the liquid LQ. Moreover, in the present embodiment, the upper surface 94 of the plate member T (substrate stage PST) is charged to the same polarity as the liquid LQ.

As one example, the present embodiment describes an exemplary case wherein the liquid LQ is (positively) charged by a positive electrode, and the surface of the substrate P and the upper surface 94 of the plate member T are (positively) charged by a positive electrode.

In the present embodiment, the substrate P contains insulating material such as a silicon wafer, and is capable of being charged to the prescribed polarity. The plate member T contains insulating material such as, for example, fluororesin material such as polytetrafluoroethylene (Teflon (registered trademark)), acrylic resin material, and silicon resin material, and is capable of being charged to the prescribed polarity.

In the present embodiment, the last optical element LS1 is formed with insulating material such as quartz or fluorite.

In addition, in the present embodiment, the nozzle member 70 is formed with insulating material. As the material forming the nozzle member 70, it is preferable to use material that has a low dielectric constant and that is lyophilic relative to the liquid LQ.

By these means, the liquid LQ that is charged by the charging apparatuses 60 is smoothly supplied to the optical path space K1 in a charged state. Moreover, the liquid immersion space LS is formed with the charged liquid LQ.

Furthermore, it is also acceptable not to form the entire nozzle member 70 with material that has a low dielectric constant and lyophilicity, and to subject at least the portion of the nozzle member 70 that contacts the liquid LQ to surface treatment (e.g., coating treatment) with material having a low dielectric constant and lyophilicity. That is, one may form a film of material having a low dielectric constant and lyophilicity on the portion that contacts the liquid LQ.

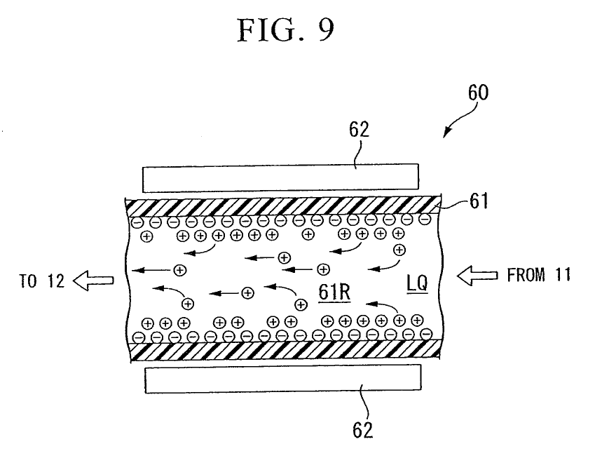

FIG. 9 is a schematic drawing that shows one example of the charging apparatus 60. In FIG. 9, the charging apparatus 60 is provided with a supply tube 61 that forms the channel 61R through which the liquid LQ flows, and electrode members 62 disposed on the outer sides of the supply tube 61 relative to the channel 61R. The channel 61R of the supply tube 61 is connected to the channel of the supply tube 13. After flowing through the supply tube 61 of the charging apparatus 60, the liquid LQ that is fed from the liquid supply apparatus 11 is sent to the supply tube 13, and is supplied to the supply port 12 via the supply channel 14.

The supply tube 61 is formed, for example, from insulating material such as, for example, fluororesin material, acrylic resin material, and silicon resin material. The electrode members 62 are capable of applying a prescribed electric field (voltage) to the supply tube 61 (the liquid LQ that flows through the supply tube 61).

When voltage is applied to the liquid LQ that flows through the supply tube 61 by the electrode members 62, electrostatic polarization occurs in the liquid LQ, the molecules of the liquid LQ are polarized, and electrical charge polarization occurs. Negative charges collect in the vicinity of the inner surfaces of the supply tube 61. Positive charges move to the supply tube 13 (supply port 12) side due to the flow of the liquid LQ. As a result, liquid LQ that is positively charged is supplied to the supply port 12. Moreover, by increasing the flow rate of the liquid LQ that flows through the supply tube 61, it is possible to more smoothly charge the liquid LQ.

In addition, the exposure apparatus EX of the present embodiment is provided with a charging apparatus 100 that charges the substrate P and the plate member T (substrate stage PST) to the prescribed polarity.

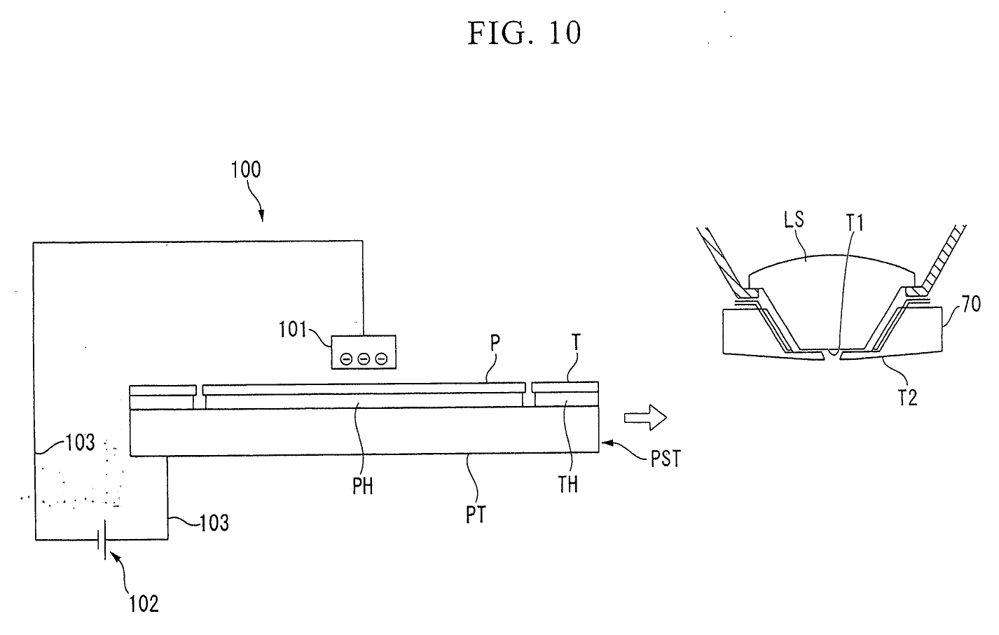

FIG. 10 is a schematic drawing that shows one example of the charging apparatus 100 that charges the substrate P and the plate member T. In FIG. 10, the charging apparatus 100 is provided with an electrode member 101 that serves to charge the surface of the substrate P and the upper surface of the plate member T. The electrode member 101 is disposed at a position that opposes the surface of the substrate P and the upper surface of the plate member T.

In the present embodiment, the charging apparatus 100 charges the substrate P that is held by the substrate holder PH of the substrate stage PST. In addition, the charging apparatus 100 charges the plate member T that is held by the plate member holder TH of the substrate stage PST.

The charging apparatus 100 is provided with a voltage generator (power source device) 102 that generates an electric field (voltage) between the surface of the substrate P and the upper surface of the plate member T and the lower surface of the electrode member 101 that opposes the surface of the substrate P and the upper surface of the plate member T. The voltage generator 102 is electrically connected to the electrode member 101 and the substrate stage PST, respectively, by a wire 103. The substrate stage PST that includes the substrate holder PH, plate member holder TH, and stage body PT is formed with insulating material.

The electrode member 101 is disposed at a position that is separated from the last optical element LS1 and nozzle member 70. The electrode member 101 is disposed, for example, in the vicinity of a substrate replacement position (loading position) where the substrate P is inserted (loaded) into the substrate stage PST prior to exposure. Furthermore, in the loading position, it is possible to perform the operation of ejecting (unloading) the substrate P from the substrate stage PST after exposure.

The substrate stage PST is disposed in the loading position, and the substrate P is loaded into the substrate stage PST prior to exposure, and is held by the substrate holder PH. The plate member T is held in the plate member holder TH.

In order to charge the substrate P and the plate member T, the control apparatus CONT energizes the electrode member 101 and the substrate stage PST using the voltage generator 102. In the present embodiment, the electrode member 101 is negatively charged. The control apparatus CONT then moves the substrate stage PST in the XY directions within a prescribed region which includes a position that opposes the lower surface of the electrode member 101. In other words, the control apparatus CONT controls the substrate stage drive apparatus PSTD so that the substrate P and the plate member T move under the electrode member 101. By this means, the surface of the substrate P and the upper surface of the plate member T are positively charged. The control apparatus CONT then adjusts the position of the substrate stage PST so that the substrate P and the plate member T that are positively charged are disposed at a position that opposes the lower surface T1 of the last optical element LS1 and the lower surface T2 of the nozzle member 70. The control apparatus CONT then forms the liquid immersion space LS between the lower surface T1 of the last optical element LS1 and the lower surface T2 of the nozzle member 70 and at least one or the other of the surface of the substrate P and the plate member T, and initiates liquid immersion exposure of the substrate P.

Furthermore, the electrode member 101 may be disposed at a position other than the loading position so long as it is a position that is separated from the last optical element LS1 and nozzle member 70, and so long as the substrate P and the plate member T are capable of moving within a prescribed region that includes a position that opposes the lower surface of the electrode member 101.

As the liquid LQ and the substrate P and plate member T are charged to the same polarity (positive), the state of the interface of the liquid LQ of the liquid immersion space LS can be set to a prescribed state, as shown in FIG. 8.

Here, the state of the interface LG being in the prescribed state includes the state where effluence, residue and the like of the liquid LQ are inhibited, and where the liquid LQ can be satisfactorily held between the liquid LQ and the last optical element LS1 and nozzle member 70 and the substrate P and plate member T.

For example, the state of the interface LG being in the prescribed state includes the state where effluence of the liquid LQ does not occur even when the substrate P (plate member T, substrate stage PST) is moved in the XY directions relative to the last optical element LS1 and the nozzle member 70, and where the position of the interface LG in the XY directions between the lower surface T2 of the nozzle member 70 and the surface of the substrate P is disposed on the inner side (optical path space K1 side) of the edge of the lower surface T2 of the nozzle member.

In addition, the state of the interface LG being in the prescribed state includes the state where the shape of the interface LG of the liquid LQ is maintained in a desired state. For example, when the shape of the interface LG is disturbed, and the liquid LQ spreads over the substrate P (plate member T) in the manner of a thin film, there is the possibility that the liquid LQ may effuse, and that it may remain on the substrate P as droplets. The shape of the interface LG being in the desired state includes a shape of the interface LG that enables inhibition of occurrence of effluence, residue and the like of the liquid LQ.

Moreover, the state of the interface LG being in the prescribed state includes the state where the contact angle θ of the surface of the substrate P (upper surface of the plate member T) and the liquid LQ is at or above a prescribed value (e.g., 80° or more, and preferably 110° or more). That is, the state of the interface LG being in the prescribed state includes the state where the contact angle θ of the surface of the substrate P and the liquid LQ increases, and the liquid repellency of the surface of the substrate P relative to the liquid LQ substantially rises. As stated above, the exposure apparatus EX of the present invention uses the local liquid immersion method, and when liquid repellency of the surface of the substrate P relative to the liquid LQ is low (when the contact angle θ of the surface of the substrate P and the liquid LQ is small), the possibility arises that the liquid LQ may not be able to be satisfactorily held. Consequently, it is desirable for the liquid repellency of the surface of the substrate P relative to the liquid LQ to be high (for the contact angle θ of the surface of the substrate P and the liquid LQ to be large).

In the present embodiment, it is possible to adjust the contact angle θ of the surface of the substrate P (upper surface of the plate member T) and the liquid LQ to a desired state. That is, in the present embodiment, it is possible to increase the contact angle θ of the surface of the substrate P and the liquid LQ, and substantially raise the liquid repellency of the surface of the substrate P relative to the liquid LQ.

As shown in FIG. 8, as the liquid LQ and the substrate P and plate member T are charged to the same polarity (positive), repulsion based on electrostatic force occurs between the liquid LQ and the substrate P (plate member T). That is, based on electrostatic force, a force arises between the interface LG of the liquid LQ of the liquid immersion space LS and the surface of the substrate P that works to mutually separate them. In particular, it is quite possible that the repulsion that occurs between the surface of the substrate P and the portion of the interface LG that is close to the surface of the substrate P will be stronger than the repulsion that occurs between the surface of the substrate P and the portion of the interface LG that is distant from the surface of the substrate P (the portion that is close to the lower surface T2 of the nozzle member 70). Due to this repulsion based on electrostatic force, as shown in FIG. 8, it is possible to enlarge the contact angle θ of the surface of the substrate P and the liquid LQ.

In a state where the substrate P and the plate member T are charged, the substrate P undergoes liquid immersion exposure. After completion of the liquid immersion exposure treatment, the substrate P is ejected (unloaded) from the substrate stage PST.

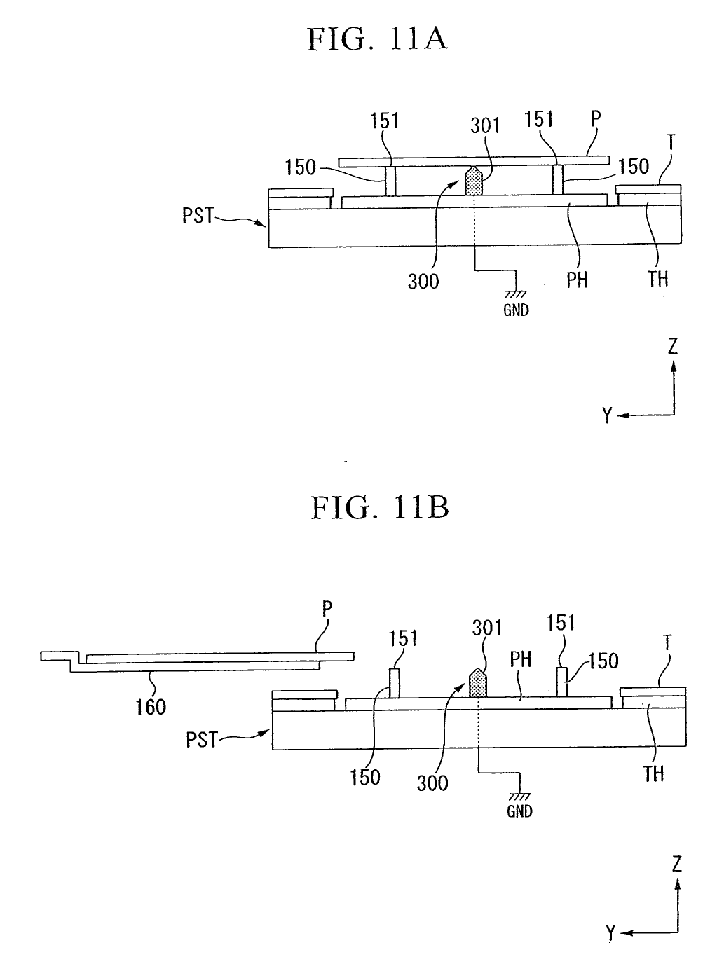

FIG. 11A and FIG. 11B are schematic drawings that show the state where the substrate P is unloaded from the substrate stage PST. As shown in FIG. 11A, the substrate stage PST is provided with support members 150 that can be raised or lowered relative to the substrate holder PH while supporting the rear surface of the substrate P. The support members 150 are rod-like members that have support faces 151 capable of supporting the rear surface of the substrate P. The support members 150 are multiply provided, and can be moved (can be raised or lowered) in the Z axial directions by a drive apparatus that is not illustrated in the drawings.

When the substrate P is being held by the substrate holder PH, the support members 150 are housed in holes that are formed in parts of the substrate stage PST (substrate holder PH).

When the substrate P is ejected form the substrate holder PH, as shown in FIG. 11A, the support members 150 are moved (raised) in the +Z direction in a state where they support the rear surface of the substrate P. By this means, as shown in FIG. 11A, the rear surface of the substrate P and the substrate holder PH are separated.

Moreover, as shown in FIG. 11B, the exposure apparatus EX is provided with a conveyor 160 that conveys the substrate P, and the control apparatus CONT uses the conveyor 160 to eject the substrate P that is separated from the substrate holder PH by the support members 150.

Furthermore, when the substrate P is loaded into the substrate stage PST prior to exposure, the support members 150 are raised, and the substrate P conveyed by the conveyor 160 is delivered to the support members 150. The support members 150 that support the substrate P are moved (lowered) in the −Z direction. By this means, the substrate P is held in the substrate holder PH.

Moreover, in the present embodiment, the exposure apparatus EX is provided with a charge neutralization apparatus 300 that neutralizes that electricity (electric charge) with which the substrate P is charged. In the present embodiment, the charge neutralization apparatus 300 neutralizes the electricity with which the substrate P is charged after liquid immersion exposure.

In the present embodiment, the charge neutralization apparatus 300 includes a conductive member 301 that is disposed in the substrate stage PST. The conductive member 301 is grounded (earthed). The conductive member 301 can be moved (can be raised and lowered) in the Z axial directions by a drive apparatus that is not illustrated in the drawings. The conductive member 301 is capable of contacting the rear surface of the substrate P. The conductive member 301 is able to neutralize the electricity (electric charge) with which the substrate P is charged by contacting the substrate P.

In the present embodiment, the liquid immersion exposure treatment terminates, the support members 150 are raised in order to raise the substrate P, and the conductive member 301 is raised, and contacts the substrate P. By this means, the electricity with which the substrate P that is unloaded from the substrate stage PST is charged is neutralized. Furthermore, it is also acceptable to bring the conductive member 301 and the substrate P into contact before the substrate P is raised.

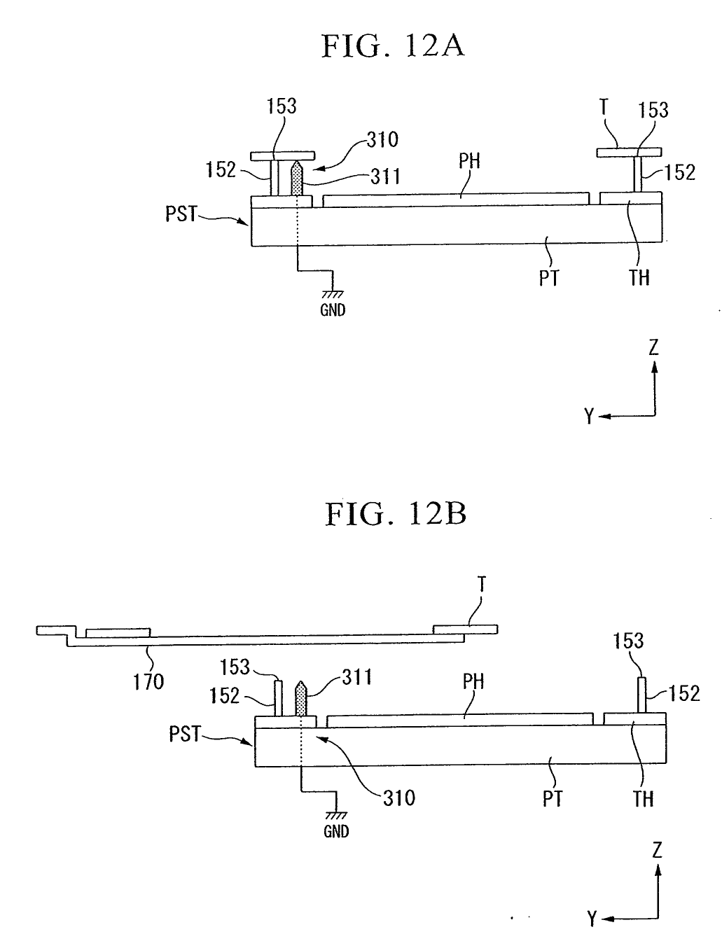

Moreover, as shown in FIG. 12A, the substrate stage PST (plate member holder TH) is also provided with support members 152 capable of being raised and lowered relative to the plate member holder TH while supporting the rear surface of the plate member T. The support members 152 are rod-like members that have support faces 153 capable of supporting the rear surface of the plate member T. The support members 152 are multiply provided, and can be moved (can be raised and lowered) in the Z axial directions by a drive apparatus that is not illustrated in the drawings.

The plate member T is capable of replacement relative to the substrate stage PST. When the plate member T is held by the plate member holder TH, the support members 152 are housed in holes that are formed in parts of the substrate stage PST (plate member holder TH).

When the plate member T is ejected from the plate member holder TH, the support members 152 that are provided in the plate member holder TH move (rise) in the +Z direction in a state where they support the rear surface of the plate member T. By this means the rear surface of the plate member T and the plate member holder TH separate.

As shown in FIG. 12B, the exposure apparatus EX is provided with a conveyor 172 that conveys the plate member T, and the control apparatus CONT uses the conveyor 170 to eject the plate member T that has been separated from the plate member holder TH by the support members 152.

Furthermore, when a new plate member T is loaded in the substrate stage PST, the support members 152 that are provided in the plate member holder TH are raised, and the plate member T that is conveyed by the conveyor 170 is delivered to the support members 152. The support members 152 that support the plate member T are moved (lowered) in the −Z direction. By this means, the plate member T is held in the plate member holder TH.

Moreover, in the present embodiment, the exposure apparatus EX is provided with a charge neutralization apparatus 310 that neutralizes the electricity (electric charge) with which the plate member T is charged. The charge neutralization apparatus 300 includes a conductive member 311 that is disposed in the substrate stage PST. The conductive member 311 is grounded (earthed). The conductive member 311 can be moved (can be raised and lowered) in the Z axial directions by a drive apparatus that is not illustrated in the drawings. The conductive member 311 is capable of contacting the rear surface of the plate member T. The conductive member 311 is able to neutralize the electricity (electric charge) with which the plate member T is charged by contacting the plate member T.

In the present embodiment, when the plate member T is ejected (replaced), the support members 152 are raised in order to raise the plate member T, and the conductive member 311 is raised, and contacts the plate member T. By this means, the electricity with which the plate member T that is unloaded from the substrate stage PST is charged is neutralized

Furthermore, it is also acceptable to bring the conductive member 311 and the plate member T into contact before the plate member T is raised. Moreover, removal of the electricity with which the plate member T is charged may be conducted regardless of whether or not ejection (replacement) operations are conducted with respect to the plate member T. For example, in cases where it is necessary to neutralize the electricity with which the plate member T is charged in a stage where it is not ejected (replaced), one may adopt a configuration where the conductive member 311 that is provided in the substrate stage PST or outside of the substrate stage PST is brought into contact with the plate member T in a state where the plate member T is still supported by the plate member holder TH.

In configurations designed so that the substrate holder PH is endowed with conductivity and the substrate P can be grounded as an electrostatic countermeasure relative to the substrate P, it is possible that the effect that causes charging of the substrate P may be attenuated, and that the desired effect may be unobtainable. In such cases, it is acceptable to provide a mechanism that enables the grounding of the substrate P to be broken.

As described above, according to the present embodiment, as the liquid LQ is charged to a prescribed polarity, and as the surface of the substrate P is charged to the same polarity as the liquid LQ, it is possible enlarge the contact angle of the surface of the substrate P and the liquid LQ. Accordingly, effluence or the like of the liquid LQ can be inhibited, and the liquid LQ can be satisfactorily held.

In order to enlarge the contact angle of the surface of the substrate P and the liquid LQ, it is conceivable, for example, that one may select a material (film) that has the desired physical properties in order to form the surface of the substrate P according to the type (physical properties) of liquid LQ that is used, arid adjust and develop the physical properties of the material (film) that forms the surface of the substrate P. However, depending on the liquid LQ that is used, it may prove difficult to select a material that has the desired physical properties, and to adjust and develop the physical properties of the material that forms the surface of the substrate P.

In the present embodiment, as the liquid immersion space LS is formed by the liquid LQ that is charged to the prescribed polarity, and as the substrate P is charged to the prescribed polarity according to the liquid LQ that is charged, it is possible to obtain an optimal contact angle θ, and to satisfactorily hold the liquid LQ regardless of the physical properties of the liquid LQ, and regardless of the physical properties and the like of the material the forms the surface of the substrate P.

### Fourth Embodiment

Next, a fourth embodiment is described. In the below description, constituent parts that are identical or equivalent to those in each of the foregoing embodiments are assigned identical symbols, and description thereof is abbreviated or omitted.

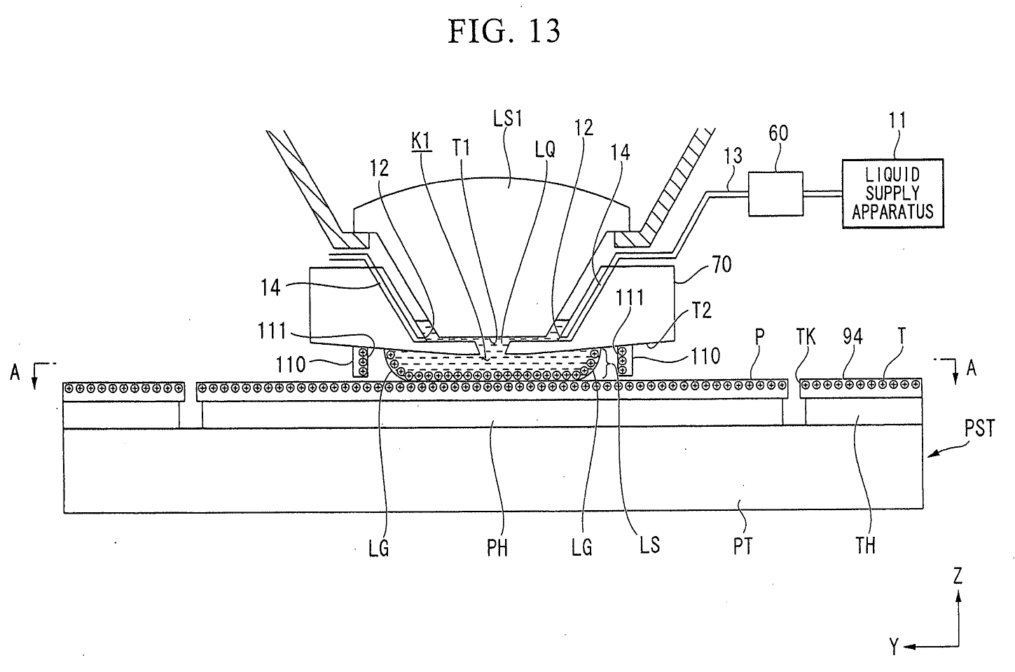

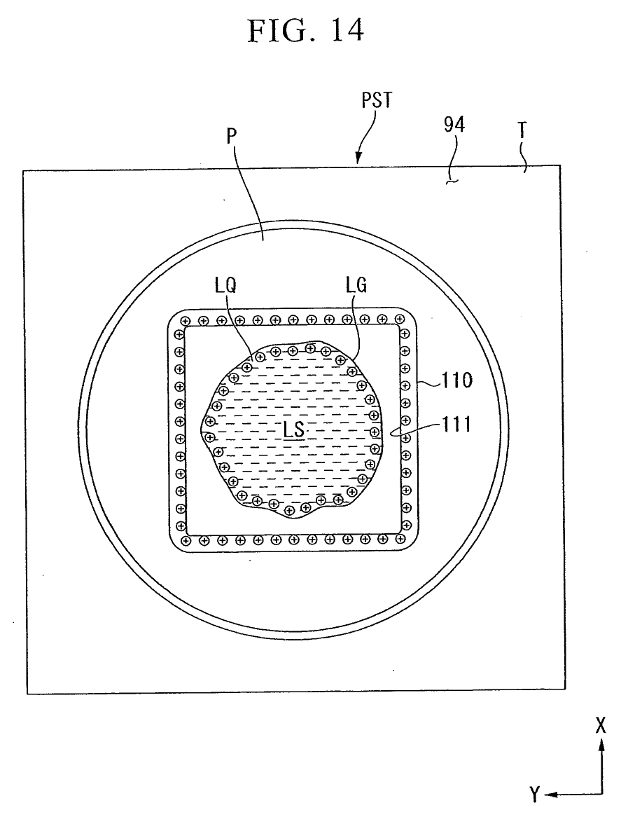

FIG. 13 is a schematic drawing that shows part of the exposure apparatus EX of the fourth embodiment FIG. 14 is a cross-sectional, fragmentary view along the A-A line of FIG. 13. The distinctive portion of the fourth embodiment is that charged members 110 are added to the exposure apparatus EX described in the aforementioned third embodiment.

In FIG. 13 and FIG. 14, in order to establish the state of the interface LG of the liquid LQ of the liquid immersion space LS in a prescribed state, the exposure apparatus EX is provided with charged members 110 that are disposed so as to surround the optical path space K1 at positions that do not contact the liquid LQ of the liquid immersion space LS, and that are charged to the same polarity as the liquid LQ of the liquid immersion space LS.

In the present embodiment, the charged members 110 are connected to a power source device that is not illustrated in the drawings, and the inner surfaces 111 of the charged members 110 that oppose the interface LG of the liquid immersion space LS are positively charged.

Moreover, in the present embodiment, the charged members 110 are supported by the lower surface T2 of the nozzle member 70. The charged members 110 may also be separated from the nozzle member 70. In this case, the charged members 110 are supported by a prescribed support mechanism between the nozzle member 70 and the substrate P so as to be separated from the nozzle member 70 and the substrate P, respectively.

In the present embodiment, the charged members 110 are constantly energized and charged by a power source device during liquid immersion exposure of the substrate P. As the liquid LQ of the liquid immersion space LS and the charged members 110 are charged to the same polarity (positive), repulsion based on electrostatic force occurs between the interface LG of the liquid immersion space LS and the inner surfaces 111 of the charged members 110. That is, based on electrostatic force, a force that impels toward mutual separation occurs between the interface LG of the liquid LQ and the inner surfaces of the charged members 110. Due to the repulsion based on electrostatic force, as shown in FIG. 13 and FIG. 14, it is possible to adjust the position of the interface LG in the XY directions between the surface of the substrate P and the lower surface 12 of the nozzle member 70.

In the present embodiment, as the inner surfaces 111 of the charged members 110 are disposed at least on the inner side (optical path space K1) side of the edge of the lower surface T2 of the nozzle member 70, even when the substrate P (plate member T and substrate stage PST) is moved in the XY directions relative to the last optical element LS1 and the nozzle member 70, it is possible to at least contain the liquid LQ on the inner side (optical path space K1 side) of the edge of the lower surface T2 of the nozzle member 70 by repulsion based on electrostatic force. By this means, it is possible to inhibit effluence of the liquid LQ toward the outer sides of the space between the nozzle member 70 and the substrate P.

Furthermore, so long as the liquid LQ can at least be contained on the inner side (optical path space K1 side) of the edge of the lower surface T2 of the nozzle member 70, the inner surfaces 111 of the charged members 110 may be disposed on the outer side of the edge of the lower surface T2 of the nozzle member 70.

Moreover, as in the above-described third embodiment, as the substrate P (plate member T) is charged to the same polarity as the liquid LQ, it is possible to maintain the contact angle θ of the surface of the substrate P and the liquid LQ at or above a prescribed value.

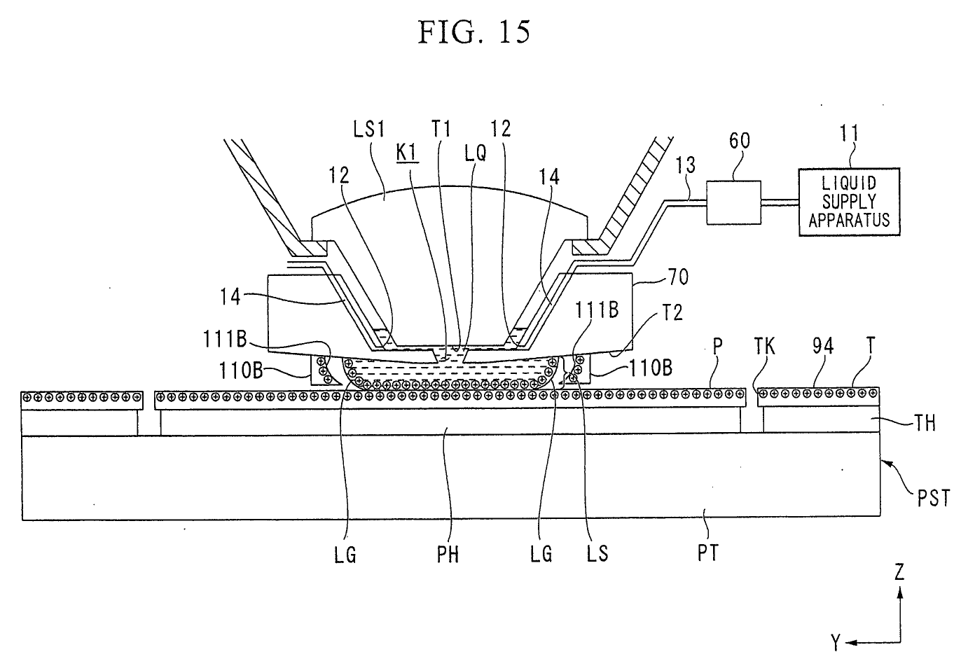

In addition, as shown in FIG. 15, as the shape of the interface LG of the liquid immersion space LS is in the desired state, it is possible to adjust the shape of inner surfaces 111B of charged members 110B. The shape of the interface LG of the liquid immersion space LS can be adjusted according to the shape of the inner surfaces 111B of the charged members 110B. In FIG. 15, as one example, the case is shown where the shape of the inner surfaces 111B within the YZ plane is arc-shaped. The shape of the inner surfaces 111B shown in FIG. 15 is an arc shape wherein the portion near the surface of the substrate P is closer to the optical path space K1 than the portion near the lower surface T2 of the nozzle member 70.

By adjusting the shape of the interface LG of the liquid immersion space LS, it is possible to inhibit the liquid LQ from spreading over the substrate P (plate member T) and creating a thin film thereon, and inhibit the liquid LQ from flowing out and remaining on the substrate P in the form of droplets.

In the present embodiment, an exemplary case is described wherein the charged members 110 (110B) are constantly energized by a power source device during liquid immersion exposure of the substrate P, but it is also acceptable, for example, to charge the charged members 110 (110B) by a power source device before liquid immersion exposure of the substrate P, and turn off the power source device when liquid immersion exposure of the substrate P is performed. Even after the power source device is turned off, so long as the charged members 110 (110B) continue to be charged, it is possible to satisfactorily hold the liquid LQ by electrostatic force.

### Fifth Embodiment

Next, a fifth embodiment is described. In the below description, constituent parts that are identical or equivalent to those in each of the foregoing embodiments are assigned identical symbols, and description thereof is abbreviated or omitted.

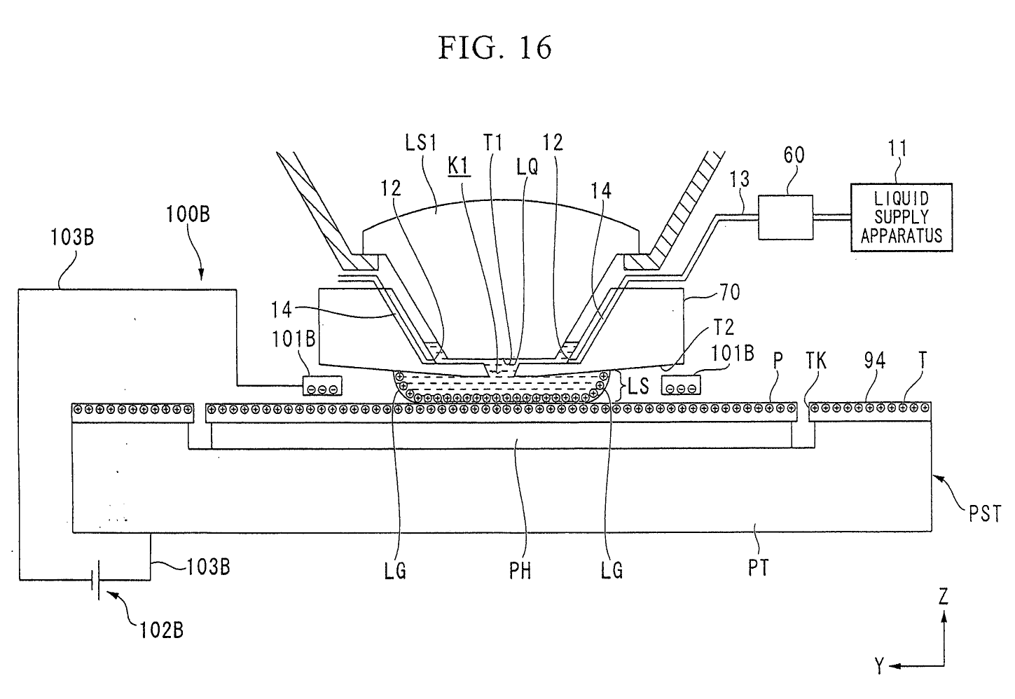

FIG. 16 is a schematic drawing that shows another example of a charging apparatus 100B that charges the substrate P and plate member T (substrate stage PST) to a prescribed polarity. In FIG. 16, the charging apparatus 100B is provided with electrode members 101B that serve to charge the surface of the substrate P and the upper surface 94 of the plate member T. The electrode members 101B are disposed at positions that oppose the surface of the substrate P and the upper surface 94 of the plate member T.

The electrode members 101B are disposed at positions that are capable of opposing the substrate P (plate member T) that is disposed at a position that opposes the lower surface T1 of the last optical element LS1 and the lower surface T2 of the nozzle member 70. A prescribed interstice is formed between the surface of the substrate P that is held by the substrate holder PH and the upper surface 94 of the plate member T that is held by the plate member holder TH and the lower surfaces of the electrode members 101B that oppose the surface of the substrate P and the upper surface 94 of the plate member T.

In the present embodiment, the electrode members 101B are disposed so as to surround the optical path space K1 of the exposure light EL at positions that do not contact the liquid LQ of the liquid immersion space LS. In the present embodiment, the electrode members 101B are rectangular frame members that surround the optical path space K1. It is also acceptable to dispose multiple (for example, four) rod-shaped electrode members 101B so that they surround the optical path space K1.

In the present embodiment, the electrode members 101B are supported between the nozzle member 70 and the substrate P by prescribed support mechanisms so as to be separated from the nozzle member 70 and the substrate P, respectively. It is also acceptable to have the electrode members 101B supported by the nozzle member 70. Moreover, the electrode members 101B may also be disposed on the outer sides of the edge of the nozzle member 70 relative to the optical path space K1 so long as the positions are capable of opposing the substrate P (plate member T) that is disposed at a position that opposes the lower surface T1 of the last optical element LS1 and the lower surface T2 of the nozzle member 70.

In the present embodiment, the charging apparatus 100B charges the substrate P that is held by the substrate holder PH of the substrate stage PST. In addition, the charging apparatus 100B charges the plate member T that is held by the plate member holder TH of the substrate stage PST.

The charging apparatus 100B is provided with a voltage generator (power source device) 102B that generates an electric field (voltage) between the surface of the substrate P and upper surface 94 of the plate member T and the lower surfaces of the electrode members 101B. The voltage generator 102B is electrically connected to the electrode members 101B and substrate stage PST, respectively, by a wire 103B.

In order to charge the substrate P and plate member T, the control apparatus CONT energizes the electrode members 101B and the substrate stage PST using the voltage generator 102B. In the present embodiment, the electrode members 101B are negatively charged. As a result, the surface of the substrate P and the upper surface 94 of the plate member T are positively charged. The control apparatus CONT then performs liquid immersion exposure of the substrate P in a state where the electrode members 101B and the substrate stage PST are energized. During liquid immersion exposure of the substrate P, the substrate stage PST is moved in the XY directions within a prescribed region including positions that oppose the lower surfaces of the electrode members 101B. As a result, during liquid immersion exposure of the substrate P, the surface of the substrate P and the upper surface 94 of the plate member T are continuously charged by the electrode members 101B.

Thus, in the present embodiment, it is possible to conduct in parallel liquid immersion exposure treatment of the substrate P and charging treatment of the surface of the substrate P and upper surface 94 of the plate member T. As a result, it is possible to always have the surface of the substrate P and the upper surface 94 of the plate member T continuously charged, and always maintain the contact angle θ of the surface of the substrate P (upper surface of the plate member T) and the liquid LQ at or above the prescribed value. Accordingly, it is possible to inhibit effluence and the like of the liquid LQ, and to conduct liquid immersion exposure of the substrate P in a state where the liquid LQ is satisfactorily held.

After completion of liquid immersion exposure, the electricity with which the substrate P is charged is neutralized by the conductive member 301 of the charge neutralization apparatus 300 that is described above in the third embodiment, and the substrate P is ejected from the substrate stage PST. Moreover, when the plate member T is replaced, the electricity with which the plate member T is charged is neutralized by the conductive member 311 of the charge neutralization apparatus 310 that is described above in the third embodiment, and the plate member T is ejected from the substrate stage PST.

### Sixth Embodiment

Next, a sixth embodiment is described. In the below description, constituent parts that are identical or equivalent to those in each of the foregoing embodiments are assigned identical symbols, and description thereof is abbreviated or omitted.

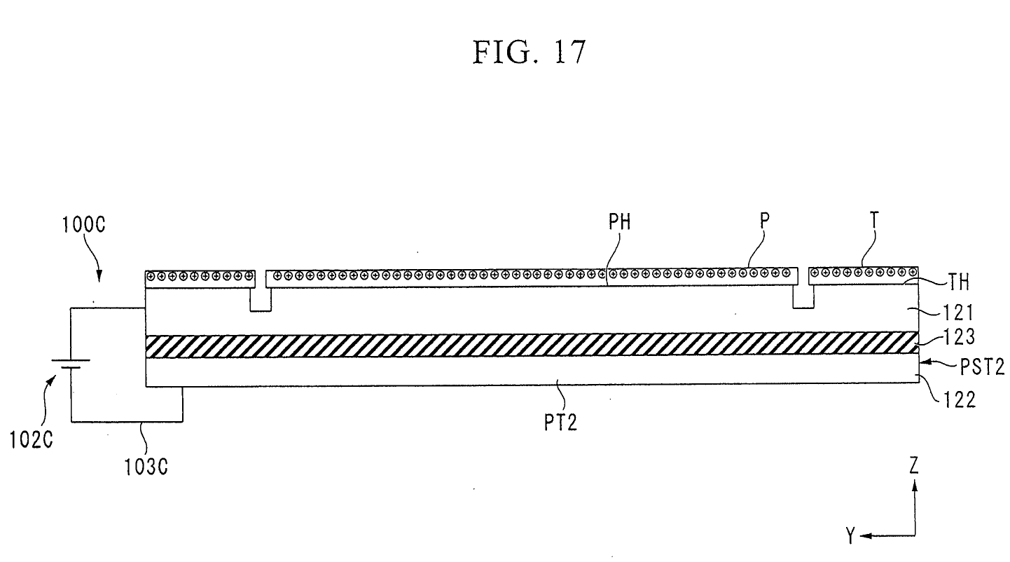

FIG. 17 is a schematic drawing that shows another example of a charging apparatus 100C that charges the substrate P and plate member T (substrate stage PST) to a prescribed polarity. The charging apparatus 100C charges the substrate P held by the substrate holder PH and the plate member T held by the plate member holder TH.

The charging apparatus 100C of the present embodiment is provided with electrode members 121 and 122 that serve to charge the surface of the substrate P and the upper surface of the plate member T. The electrode members 121 and 122 are disposed on the substrate stage PST2. As with the above-described second to fifth embodiments, the liquid LQ is positively charged. The charging apparatus 100C positively charges the surface of the substrate P and the upper surface of the plate member T.

The stage body PT2 includes the first electrode member 121 and second electrode member 122, and a dielectric layer 123 that has a prescribed dielectric constant. The dielectric layer 123 is disposed between the first electrode member 121 and second electrode member 122. The substrate holder PH and plate member holder TH are disposed on the first electrode member 121 so as to connect to the first electrode member 121. In the present embodiment, the substrate holder PH and plate member holder TH are formed with a first material that is identical to that of the first electrode member 121, and the first electrode member 121, substrate holder PH, and plate member holder TH are integrated.

The charging apparatus 100C is provided with a voltage generator (power source device) 102C that generates an electric field (voltage) between the first electrode member 121 and second electrode member 122. The voltage generator 102C is electrically connected to the first electrode member 121 and second electrode member 122, respectively, by the wire 103C.

In order to charge the substrate P and plate member T, the control apparatus CONT energizes the first electrode member 121 and second electrode member 122 using the voltage generator 102C. In the present embodiment, the first electrode member 121 is positively charged. As a result, the surface of the substrate P and the upper surface 94 of the plate member T are positively charged. The substrate holder PH supports the rear surface of the substrate P, and the plate member holder TH supports the rear surface of the plate member T. When the first electrode member 121 is positively charged, the surface of the substrate P and the upper surface of the plate member T that are supported by the substrate holder PH and plate member holder TH are positively charged. The control apparatus CONT then performs liquid immersion exposure of the substrate P in a state where the first electrode member 121 and second electrode member 122 are energized. As a result, even during liquid immersion exposure of the substrate P, it is possible to have the surface of the substrate P and the upper surface of the plate member T continuously charged, and always maintain the contact angle θ of the surface of the substrate P and upper surface of the plate member T and the liquid LQ at or above the prescribed value. Accordingly, it is possible to inhibit effluence and the like of the liquid LQ, and to conduct liquid immersion exposure of the substrate P in a state where the liquid LQ is satisfactorily held.

After completion of liquid immersion exposure, the electricity with which the substrate P is charged is neutralized by the conductive member 301 of the charge neutralization apparatus 300 that is described above in the third embodiment, and the substrate P is ejected from the substrate stage PST. Moreover, when the plate member T is replaced, the electricity with which the plate member T is charged is neutralized by the conductive member 311 of the charge neutralization apparatus 310 that is described above in the third embodiment, and the plate member T is ejected from the substrate stage PST.

### Seventh Embodiment

Next, a seventh embodiment is described. In the below description, constituent parts that are identical or equivalent to those in each of the foregoing embodiments are assigned identical symbols, and description thereof is abbreviated or omitted.

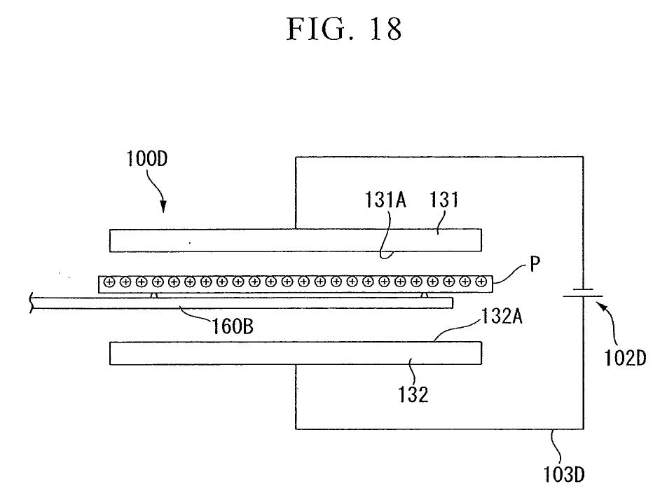

FIG. 18 is a schematic drawing that shows another example of a charging apparatus 100D that charges the substrate P to a prescribed polarity. The charging apparatus 100D of the present embodiment charges the substrate P before it is held by the substrate holder PH. The charging apparatus 100D positively charges the surface of the substrate P.

The charging apparatus 100D is provided with a first electrode member 131 that has a lower surface 131A, a second electrode member 132 that has an upper surface 132A that opposes the lower surface 131A of the first electrode member 131, and a voltage generator (power source device) 102D that generates an electric field (voltage) between the lower surface 131A of the first electrode member 131 and the upper surface 132A of the second electrode member 132. The voltage generator 102D is electrically connected to the first electrode member 131 and second electrode member 132, respectively, by the wire 103D.

The first and second electrode members 131 and 132 are disposed at positions that are separated from the last optical element LS1 and nozzle member 70. The first and second electrode members 131 and 132 are disposed, for example, in the vicinity of the substrate replacement position (unloading position) where the substrate P is inserted (loaded) into the substrate stage PST prior to exposure.

Moreover, the exposure apparatus EX is provided with a conveyor 160B that delivers the substrate P to the substrate stage PST prior to exposure. The conveyor 160B is formed with insulating material. As shown in FIG. 18, before the substrate P is loaded into the substrate stage PST prior to exposure, the conveyor 160B disposes the substrate P that it supports between the first electrode member 131 and second electrode member 132. In order to charge the substrate P in a state where the substrate P has been disposed between the first electrode member 131 and second electrode member 132 by the conveyor 160B, the control apparatus CONT respectively energizes the first electrode member 131 and second electrode member 132 using the voltage generator 102D. As a result, the surface of the substrate P is positively charged. As the conveyor 160B that supports the substrate P is made of insulating material, the substrate P can be smoothly charged.

In the present embodiment, when the substrate P is charged using the charging apparatus 100D, the control apparatus CONT uses the conveyor 160B to move the substrate P relative to the first and second electrode members 131 and 132 so that it is scanned in the XY directions. Furthermore, when the substrate P is charged using the charging apparatus 100D, the substrate P may be approximately stationary relative to the first and second electrode members 131 and 132.

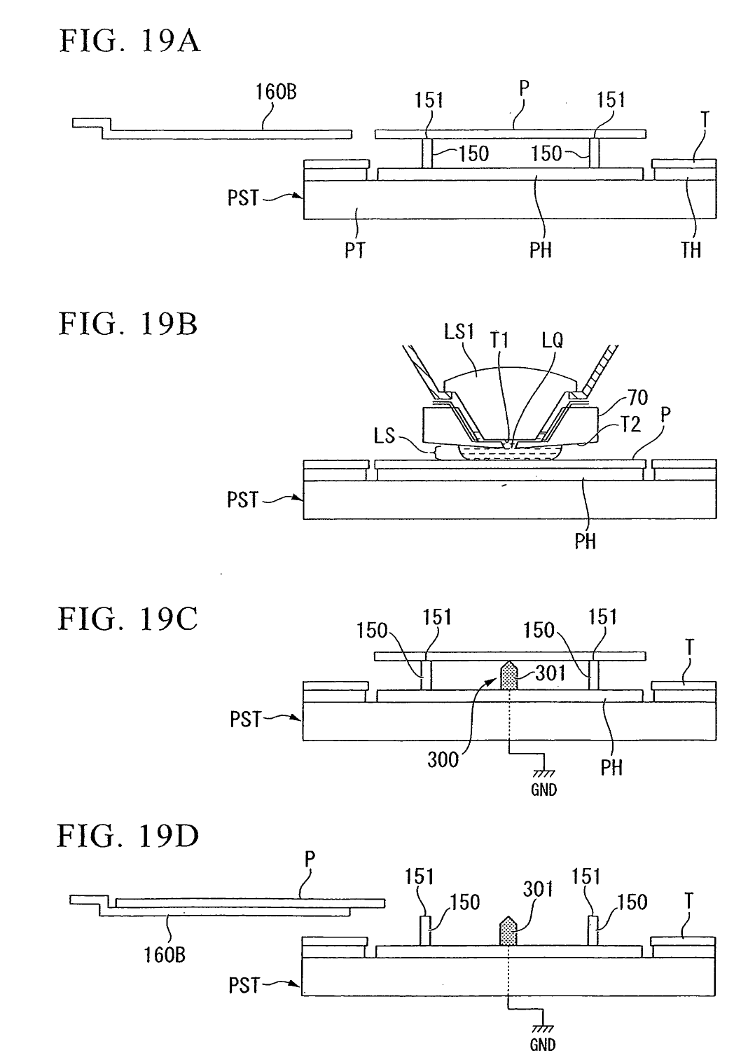

FIGS. 19A, 19B, 19C, and 19D are schematic drawings that show one example of the operation of the exposure apparatus EX of the present invention. FIG. 19A is a drawing that shows the operations for loading the substrate P into the substrate stage PST prior to exposure, using the conveyor 160B. Furthermore, as described with reference to FIG. 18, the substrate P is already charged by the charging apparatus 100D before loading into the substrate stage PST (before being held by the substrate holder PH).

As shown in FIG. 19A, the support members 150 are raised in order to load the substrate P into the substrate holder PH prior to exposure. The support members 150 have a configuration that is equivalent to that of the support members 150 described above in the third embodiment. The conveyor 160B delivers the substrate P to the support members 150 prior to exposure. The support members 150 support the substrate P that is delivered by the conveyor 160B with the support surfaces 151. The support members 150 that support the substrate P are moved (lowered) in the −Z direction As a result, the substrate P is held by the substrate holder PH.

In the present embodiment, the support members 150 are formed with insulating material. Moreover, the substrate stage PST that includes the substrate holder PH, plate member holder TH, and stage body PT is formed with insulating material. As a result, it is possible to satisfactorily maintain the charged state of the substrate P.

Liquid immersion exposure of the substrate P is performed as shown in FIG. 19B. The substrate P undergoes liquid immersion exposure in a charged state. As a result, the liquid LQ of the liquid immersion space LS is satisfactorily held. When the substrate P is being held by the substrate holder PH, the support members 150 are housed in the holes formed in parts of the substrate stage PST (substrate holder PH).

In order to unload the substrate P from the substrate holder PH after completion of liquid immersion exposure, as shown in FIG. 19C, the support members 150 are moved (raised) in the +Z direction in a state where they support the rear surface of the substrate P. As a result, the rear surface of the substrate P is separated from the substrate holder PH.

After liquid immersion exposure, the control apparatus CONT neutralizes the electricity with which the substrate P is charged using the charge neutralization apparatus 300. The charge neutralization apparatus 300 has a configuration equivalent to that of the charge neutralization apparatus 300 that is described above in the third embodiment. The charge neutralization apparatus 300 includes a conductive member 301 that is grounded (earthed), and the electricity (charge) with which the substrate P is charged is neutralized by the contact of the conductive member 301 and the substrate P. When liquid immersion exposure treatment of the substrate P is completed, the control apparatus CONT raises the support members 150 in order to raise the substrate P, raises the conductive member 301, and brings the conductive member 301 and the substrate P into contact.

As shown in FIG. 19D, the control apparatus CONT then uses the conveyor 160B to eject the substrate P that has been separated from the substrate holder PH by the support members 150.

In the present embodiment, an exemplary case is described where the charging apparatus 100D is used to charge the substrate P before it is held by the substrate holder PH, but it is also possible to use the charging apparatus 100D to charge the plate member T before it is held by the plate member holder TH. In this case, the plate member T that is supported by the conveyor 170 described above in the third embodiment is disposed between the first electrode member 131 and second electrode member 132 of the charging apparatus 100D. By using insulating material to make the conveyor 170 that conveys the plate member T before it is loaded into the plate member holder TH, it is possible to smoothly charge the plate member T. Moreover, by using insulating material to form the support members 152 that support the plate member T (the plate member T that is delivered from the conveyor 170) before it is held by the plate member holder TH, it is possible to satisfactorily maintain the charged state of the plate member T. When the plate member T is ejected from the plate member holder TH for purposes of replacement, the electricity with which the plate member T is charged can be neutralized using the conductive member 311 of the charge neutralization apparatus 310. It should be noted that the support members 152 and the charge neutralization apparatus 310 have configurations equivalent to those of the support members 152 and the charge neutralization apparatus 310 that were described above in the third embodiment.

### Eighth Embodiment

Next, an eighth embodiment is described. In the below description, constituent parts that are identical or equivalent to those in each of the foregoing embodiments are assigned identical symbols, and description thereof is abbreviated or omitted.

FIG. 20 is a schematic drawing that shows one example of the charging apparatus 100E that charges the substrate P before it is held by the substrate holder PH. The charging apparatus 100E of the present embodiment includes a corona charger 180. The corona charger 180 charges the surface of the substrate P by guiding the ions generated by corona discharge to the surface of the substrate P. The corona charger 180 may adopt a scolotron charging system that has a grid electrode between a corona wire and the substrate P, or it may adopt a colotron charging system that does not have a grid electrode.

The corona charger 180 is disposed at a position that is separated from the last optical element LS1 and the nozzle member 70. The corona charger 180 is disposed, for example, in the vicinity of the substrate replacement position (loading position) where the substrate P is inserted (loaded) into the substrate stage PST prior to exposure.

As shown in FIG. 20, the conveyor 160B that is formed with insulating material disposes the substrate P that it supports at a position opposite the corona charger 180, before the substrate P is loaded into the substrate stage PST prior to exposure. In a state where the discharge face (ion emission face) of the corona discharger 180 opposes the surface of the substrate P, the control apparatus CONT causes ionic discharge from the corona charger 180 in order to charge the substrate P. As a result, the surface of the substrate P is charged. As the conveyor 160B that supports the substrate P is made of insulating material, it is possible to smoothly charge the substrate P. The charged substrate P is loaded into the substrate holder PH in the same sequence as the sequence described above in the seventh embodiment.

Using the charging apparatus 100E that includes the corona charger 180, it is possible to charge the plate member T before it is held by the plate member holder TH.

The charging apparatus 100E that includes the corona charger 180 can also be used as the charged members 110 that are shown, for example, in FIG. 13 and FIG. 14 of the fourth embodiment. In this case, the charging apparatus 100E is disposed in the vicinity of the liquid immersion space LS, enables the surface (the upper surface 94) of the substrate P (the plate member T) to be constantly charged during exposure, and enables obtainment of the same effects as the fourth embodiment.

With respect to the foregoing second to eighth embodiments, the charging apparatus 60 using the electrode members 62 is used in order to charge the liquid LQ, but it is possible to omit the charging apparatus 60. For example, if the liquid LQ can be charged by having the liquid LQ flow in the channels of the tubes (supply tubes) that connect to the supply ports 12, it is possible to charge the liquid LQ before it is supplied to the supply ports 12 even if the electrode members 62 and the like are omitted. In this case, by adjusting at least one among the material of the tubes, inner diameter (size) of the tubes (channels), shape of the channels, and flow rate of the liquid LQ that flows through the channels, it is possible to smoothly charge the liquid LQ merely by the flow of the liquid LQ through the channels. For example, it is possible to charge the liquid LQ by forming the tubes with insulating material, narrowing (reducing the inner diameter of) the channels of the tubes, and having the liquid LQ flow at a high flow rate.

With respect to the foregoing embodiments, in the first and second embodiments, the liquid immersion region LR is held by generating a force of mutual attraction by electrostatic force that acts between the liquid LQ that is charged and the electrodes that are provided on the nozzle member 70. In contrast, in the third to the eighth embodiments, by charging the substrate P or the plate member T or the like to the same polarity as the polarity of the liquid LQ that is charged, the substrate P or the plate member T or the like is endowed with liquid repellency by the electrostatic force that acts between the two. These two configurations may be used in a mutual combination, wherein, for example, the electrodes that are provided on the nozzle member 70 may be charged to a positive polarity, and the liquid LQ as well as the substrate P and plate member T may be negatively charged. In this manner, it is possible to have an appropriate combination of the two configurations that takes into account their mutual effects.

Otherwise, in the foregoing embodiments, in the case where effects are produced on wafers by charging, the degree of charging may be adjusted taking into account the level of effects.

In each of the foregoing embodiments, an optical element LS1 is attached to the distal end of the projection optical system PL, and the optical properties—e.g., aberration (spherical aberration, comatic aberration, and so on)—of the projection optical system PL can be adjusted by this lens. As the optical element LS1 that is attached to the distal end of the projection optical system PL, it is also acceptable to have an optical plate that is used to adjust the optical properties of the projection optical system PL. Or one may use a plane parallel plate that is capable of transmitting the exposure light EL.

In cases where the pressure between the substrate P and the optical element at the distal end of the projection optical system PL that is produced by the flow of the liquid LQ is large, it is acceptable to have a firmly fixed structure wherein the optical element is not replaceable, and the optical element is immobile due to the pressure.

In the above embodiments, the configuration is one in which a liquid LQ is filled between the projection optical system PL and the surface of the substrate P, but it may also be a configuration in which the liquid LQ is filled in a status in which a cover glass consisting of a plane-parallel plate is attached to the surface of the substrate P, for example.

Furthermore, in the embodiments discussed above, the optical path on the image plane side of the last optical element of the projection optical system is filled with the liquid; however, it is possible to use a projection optical system wherein the optical path on the mask side of the last optical element is also filled with the liquid as disclosed in, for example, PCT International Publication No. WO2004/019128.

Furthermore, although the liquid LQ in the present embodiment is water or decalin, it may be a liquid other than water or decalin; for example, if the light source of the exposure light EL is an F2 laser, the light of which does not transmit through water, then it is acceptable to use a fluorine based fluid that is capable of transmitting F2 laser light, such as perfluorinated polyether (PFPE) or fluorine based oil, as the liquid LQ. In this case, portions that contact the liquid LQ are lyophilically treated by forming a thin film with, for example, a substance that has a molecular structure that contains fluorine or the like and has low polarity. In addition, it is also possible to use, as the liquid LQ, a liquid (e.g., cedar oil) that is transparent to the exposure light EL, has the highest possible refractive index, and is stable with respect to the projection optical system PL and the photoresist that is coated on the front surface of the substrate P.

In addition, a liquid that has a refractive index of approximately 1.6 to 1.8 may be used as the liquid LQ. The optical element LS1 may be formed from a material that has a refractive index that is higher than that of quartz and/or fluorite (e.g., 1.6 or greater).

The optical element may be formed from a mono-crystalline material such as a fluoride compound such as calcium fluoride (fluorite), barium fluoride, strontium fluoride, lithium fluoride, and sodium fluoride. Examples of materials having a refractive index of 1.6 or more include the sapphire and germanium dioxide disclosed in PCT International Patent Publication No. WO2005/059617, or the potassium chloride (which has a refractive index of approximately 1.75) and the like disclosed in PCT International Patent Publication No. WO 2005/059618. Liquids used for the immersion include, other than the water and decalin, for example, predetermined liquids having a C—H bond or an O—H bond such as isopropanol having a refractive index of approximately 1.50, glycerol (glycerin) having a refractive index of approximately 1.61, and predetermined liquids (i.e., organic solvents) such as hexane, heptane, decane. Moreover, the liquid may also be a mixture of any desired two or more liquids chosen from among these, or may be a mixture of pure water and at least one added (i.e., admixed) liquid chosen from among these. Furthermore, the liquid may also be obtained by adding (i.e., admixing) a salt or an acid such as H⁺, Cs⁺, K⁺, Cl⁺, SO₄²⁻ or the like to pure water, or by adding (i.e., admixing) fine particles of aluminum oxide or the like to pure water. Note also that the immersion liquid is preferably one that has a low absorption coefficient of light, that has low temperature dependency, and that exhibits stability towards the photosensitive material (or the top coat film or anti-reflection film or the like) coated on the projection optical system and/or the surface of the substrate. It is possible to provide a top coat that protects the photosensitive material and the substrate from the liquid on the substrate.

Furthermore, the substrate P in each of the embodiments discussed above is not limited to a semiconductor wafer for fabricating semiconductor devices, but can also be adapted to, for example, a glass substrate for display devices, a ceramic wafer for thin film magnetic heads, the original plate of a mask or a reticle (synthetic quartz or a silicon wafer) that is used by an exposure apparatus, or a film member or the like. In addition, the shape of the substrate is not limited to being a circular shape, and may be another shape such as a rectangle or the like.

The exposure apparatus EX can also be adapted to a step-and-scan type scanning exposure apparatus (a scanning stepper) that scans and exposes the pattern of the mask M by synchronously moving the mask M and the substrate P, as well as to a step-and-repeat type projection exposure apparatus (a stepper) that successively steps the substrate P and performs a full field exposure of the pattern of the mask M with the mask M and the substrate P in a stationary state.

In addition, the exposure apparatus EX can also be adapted to an exposure apparatus that uses a projection optical system (e.g., a dioptric projection optical system that does not include a catoptric element and has a ⅛ reduction magnification) to expose the substrate P with a reduced image of the full field of a first pattern in a state wherein the first pattern and the substrate P are substantially stationary. In this case, the exposure apparatus EX can also be adapted to a stitching type full-field exposure apparatus that subsequently further uses that projection optical system to expose the substrate P with a reduced image of the full field of a second pattern, in a state wherein the second pattern and the substrate P are substantially stationary, so that the second pattern partially overlaps the first pattern. In addition, the stitching type exposure apparatus can also be adapted to a step-and-stitch type exposure apparatus that transfers at least two patterns onto the substrate P so that they are partially superposed, and sequentially steps the substrate P.

In addition, the present invention can also be adapted to a twin stage type exposure apparatus, which comprises a plurality of substrate stages, as disclosed in, for example, Japanese Patent Application Publication No. H10-163099, Japanese Patent Application Publication No. H10-214783 (corresponding to U.S. Pat. Nos. 6,341,007, 6,400,441, 6,549,269, and 6,590,634), and Published Japanese translation No. 2000-505958 of PCT International Publication (corresponding to U.S. Pat. No. 5,969,441).

Furthermore, the present invention can be applied to an exposure apparatus provided with a substrate stage that holds a substrate and with a measurement stage on which a measurement member which is, for example, a reference member formed with a reference mark and/or various kinds of photoelectric sensor, as disclosed, for example, in the Japanese Patent Application Publication No. H11-135400 (corresponding to PCT International Publication No. WO 1999/23692) and the Japanese Patent Application, Publication No. 2000-164504 (corresponding to U.S. Pat. No. 6,897,963). In the case, as described in for example the third and fifth embodiments, by charging the upper surface of the measurement stage using the charging apparatuses 100 and 100B, the liquid LQ in the liquid immersion space LS formed between the lower face T1 of the last optical element LS1 and the lower face T2 of the nozzle member 70 on one side and the upper surface of the measurement stage on the other side can be maintained in a prescribed state. Also, as described in the sixth embodiment, the first and the second electrode members 121 and 122 can be disposed on the measurement stage.

The type of exposure apparatus EX is not limited to a semiconductor device fabrication exposure apparatus that exposes the substrate P with the pattern of a semiconductor device, but can also be widely adapted to exposure apparatuses that are used for fabricating, for example, liquid crystal devices or displays, and to exposure apparatuses that are used for fabricating thin film magnetic heads, image capturing devices (CCDs), micromachines, MEMS devices, DNA chips, or reticles and masks.

In the embodiments discussed above, a light transmitting type mask is used wherein a prescribed shielding pattern (or a phase pattern or a dimming pattern) is formed on a light transmitting substrate; however, instead of such a mask, or an electronic mask, wherein a transmittance pattern, a reflected pattern, or a light emitting pattern is formed based on electronic data of the pattern to be exposed, may be used as disclosed in, for example, U.S. Pat. No. 6,778,257.

In addition, by forming interference fringes on the substrate P as disclosed in, for example, PCT International Publication WO2001/035168, the present invention can also be adapted to an exposure apparatus (a lithographic system) that exposes the substrate P with a line-and-space pattern.

As far as is permitted, the disclosures in all of the Publications and U.S. patents related to exposure apparatuses and the like cited in the above respective embodiments and modified examples, are incorporated herein by reference.

As described above, the exposure apparatus EX is manufactured by assembling various subsystems, including each constituent element, so that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus EX from the various subsystems includes, for example, the mechanical interconnection of the various subsystems, the wiring and connection of electrical circuits, and the piping and connection of the atmospheric pressure circuit. Naturally, prior to performing the process of assembling the exposure apparatus EX from these various subsystems, there are also the processes of assembling each individual subsystem. When the process of assembling the exposure apparatus EX from the various subsystems is complete, a comprehensive adjustment is performed to ensure the various accuracies of the exposure apparatus EX as a whole. Furthermore, it is preferable to manufacture the exposure apparatus EX in a clean room wherein, for example, the temperature and the cleanliness level are controlled.

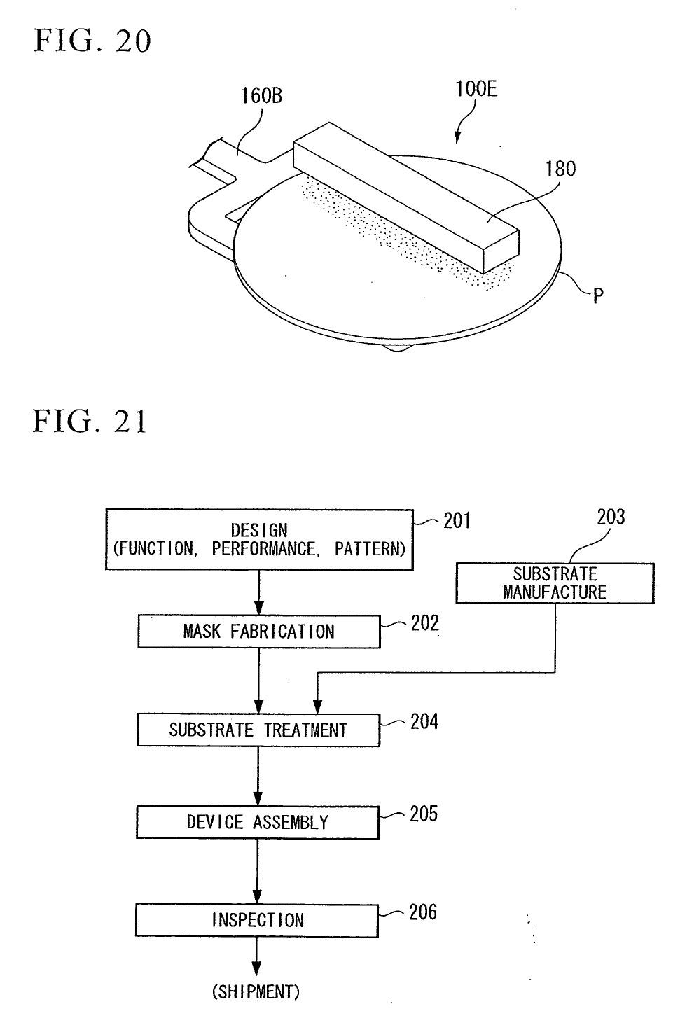

As shown in FIG. 21, a micro-device, such as a semiconductor device, is manufactured by: a step 201 that designs the functions and performance of the micro-device; a step 202 that fabricates a mask (a reticle) based on this designing step; a step 203 that fabricates a substrate, which is the base material of the device; a substrate processing step 204 that comprises a substrate process (exposure process) that includes, in accordance with the embodiments discussed above, exposing the substrate with the exposure light using the mask pattern and the exposure apparatus EX in the above embodiments and developing the exposed substrate; a device assembling step 205 (which includes fabrication processes such as dicing, bonding, and packaging processes); an inspecting step 206; and the like.

1. A liquid holding apparatus which holds a liquid in a prescribed region between a first object and a second object, comprising:
an electrostatic holder which holds the liquid by electrostatic force.

2. The liquid holding apparatus according to claim 1, wherein the electrostatic holder includes electrodes that have mutually different polarities.

3. The liquid holding apparatus according to claim 1, wherein the electrodes are disposed on the first object, and are positioned at ends of the prescribed region.

4. The liquid holding apparatus according to claim 1, wherein the liquid is charged to a prescribed polarity, and the electrostatic holder includes electrodes of a polarity that differs from the prescribed polarity.

5. The liquid holding apparatus according to claim 4, wherein the electrostatic holder further includes a charging apparatus that charges the liquid to the prescribed polarity.

6. An exposure apparatus which exposes a substrate with an image of a pattern via a liquid immersion region, and which uses the liquid holding apparatus according to claim 1 in order to farm the liquid immersion region.

7. The exposure apparatus according to claim 6, wherein the liquid immersion region is formed between the substrate and an optical member that emits an exposure light beam toward the substrate.

8. The exposure apparatus according to claim 7, wherein the liquid immersion region is formed between the optical member and a portion of the substrate.

9. The exposure apparatus according to claim 6, wherein a channel is provided in the first object through which a fluid flows.

10. The exposure apparatus according to claim 9, wherein the fluid is a liquid which is supplied to the liquid immersion region.

11. The exposure apparatus according to claim 6, further comprising a liquid supply apparatus which supplies a liquid to the liquid immersion region, wherein
at least a portion of what constitutes the electrostatic holder is disposed in a portion of the liquid supply apparatus.

12. The exposure apparatus according to claim 6, wherein the second object is the substrate.

13. The exposure apparatus according to claim 6, further comprising a substrate holder which holds the substrate, wherein
the second object is the substrate holder.

14. A device fabricating method which uses the exposure apparatus according to claim 6.

15. A liquid holding method for holding liquid in a prescribed region between a first object and a second object, the method comprising:
holding liquid with electrostatic force.

16. An immersion exposure apparatus which exposes a substrate with exposure light via a liquid in an immersion space, comprising:
an immersion member that has a predetermined face and between which and a surface of an object the immersion space can be formed, the object facing the predetermined face; and
a supply port that supplies a liquid to the immersion space, wherein
the immersion space is formed with the liquid which is charged to a prescribed polarity in order to set an interface of the liquid of the immersion space to a prescribed state.

17. The immersion exposure apparatus according to claim 16, wherein the supply port is disposed at the liquid immersion member.

18. The immersion exposure apparatus according to claim 16, further comprising:
a flow path in which the liquid flows, the flow path being in fluid communication with the supply port,
wherein the liquid is charged before supply from the supply port.

19. The immersion exposure apparatus according to claim 16, wherein the state of the interface comprises a position of the interface between the predetermined face and the surface of the object.

20. The immersion exposure apparatus according to claim 16, wherein the state of the interface comprises a shape of the interface.

21. The immersion exposure apparatus according to claim 16, wherein the state of the interface comprises a contact angle between the surface of the object and the liquid.

22. The immersion exposure apparatus according to claim 16, further comprising:
a charged member that is disposed so as to surround an optical path of the exposure light at a position where the charged member does not contact the immersion space, and that is charged to the same polarity as the liquid, in order to establish a prescribed state of the interface.

23. The immersion exposure apparatus according to claim 16, wherein the object is charged to the same polarity as the liquid in order to establish a prescribed state of the interface.

24. The immersion exposure apparatus according to claim 16, further comprising:
a charged member that is disposed so as to surround an optical path of the exposure light at a position where the charged member contacts the immersion space, and that is charged to a different polarity from that of the liquid, in order to establish a prescribed state of the interface.

25. The immersion exposure apparatus according to claim 23, further comprising:
a first charging apparatus that charges the object.

26. The immersion exposure apparatus according to claim 25, wherein the object comprises the substrate.

27. The immersion exposure apparatus according to claim 25, further comprising:
a substrate holding member that holds the substrate onto which the exposure light is irradiated,
wherein the object comprises the substrate holding member.

28. The immersion exposure apparatus according to claim 25, wherein
the first charging apparatus comprises an electrode member by which a surface of the object is charged, and
the electrode member is disposed at a position facing the surface of the object.

29. The immersion exposure apparatus according to claim 25, wherein
the first charging apparatus comprises an electrode member by which a surface of the object is charged, and
the electrode member is disposed on the object.

30. The immersion exposure apparatus according to claim 26, further comprising:
a charge neutralization apparatus that neutralizes the electricity with which the object is charged.

31. The immersion exposure apparatus according to claim 26, further comprising:
a substrate holding member that holds the substrate onto which the exposure light is irradiated,
wherein the first charging apparatus charges the substrate before the substrate holding member holds the substrate.

32. The immersion exposure apparatus according to claim 26, further comprising:
a substrate holding member that holds the substrate onto which the exposure light is irradiated,
wherein the first charging apparatus charges the substrate which has been held by the substrate holding member.

33. The immersion exposure apparatus according to claim 31, wherein
the first charging apparatus comprises an electrode member by which the substrate is charged, and
the electrode member is disposed at a position facing the surface of the substrate.

34. The immersion exposure apparatus according to claim 31, wherein
the first charging apparatus comprises an electrode member by which the substrate is charged, and
the electrode member is disposed on the substrate holding member.

35. The immersion exposure apparatus according to claim 31, wherein
an immersion exposure is executed while the substrate is charged, and
the immersion exposure apparatus further comprises a charge neutralization apparatus that neutralizes the electricity with which the substrate after the immersion exposure is charged.

36. The immersion exposure apparatus according to claim 16, further comprising:
a second charging apparatus that charges the liquid.

37. The immersion exposure apparatus according to claim 36, wherein the second charging apparatus charges the liquid before supply from the supply port.

38. A device fabricating method comprising:
exposing a substrate using an immersion exposure apparatus according to claim 16; and
developing the exposed substrate.

39. An exposure method which exposes a substrate with exposure light via a liquid in an immersion space, the method comprising:
forming the immersion space with a liquid which is charged to a prescribed polarity in order to set an interface of the liquid of the immersion space to a prescribed state.

40. A device fabricating method comprising:
exposing a substrate with the exposure method according to claim 39; and
developing the exposed substrate.
